(19) United States
(12) Patent Application Publication
(10) Pub. No.: US 2026/0136557 A1
(43) Pub. Date: May 14, 2026

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Hyun Seung YOO, Icheon-si Gyeonggi-do (KR); Eun Mee KWON, Icheon-si Gyeonggi-do (KR); Eun Seok CHOI, Icheon-si Gyeonggi-do (KR)

(73) Assignee: SK hynix Inc., Icheon-si Gyeonggi-do (KR)

(21) Appl. No.: 19/032,256

(22) Filed: Jan. 20, 2025

(30) Foreign Application Priority Data
Jul. 31, 2024 (KR) 10-2024-0101461
Dec. 10, 2024 (KR) 10-2024-0182791

(51) Int. Cl. H10B 43/35; H10B 43/27; H10B 80/00; H10W 90/00; H10W 90/20

(52) U.S. Cl. CPC H10B 43/35; H10B 43/27; H10B 80/00; H10W 90/20; H10W 90/792

(57) ABSTRACT

A semiconductor device including: a gate structure including insulating layers and conductive layers that are alternately stacked; a slit structure extending through the gate structure; a channel layer extending through the gate structure; a data storage layer including a first portion located between each of the conductive layers and the channel layer, a second portion located between each of the insulating layers and the slit structure, and a third portion extending in a horizontal direction to connect the first portion and the second portion to each other; and tunneling patterns located between the conductive layers and the channel layer, respectively, and separated from each other by the insulating layers.

### CROSS-REFERENCE TO RELATED APPLICATION

The present application claims priority under 35 U.S.C. § 119(a) to Korean Patent Application No. 10-2024-0101461 filed on Jul. 31, 2024, and Korean Patent Application No. 10-2024-0182791 filed on Dec. 10, 2024, in the Korean Intellectual Property Office, which applications are incorporated herein by reference in their entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including insulating layers and conductive layers that are alternately stacked; a slit structure extending through the gate structure; a channel layer extending through the gate structure; a data storage layer including a first portion located between each of the conductive layers and the channel layer, a second portion located between each of the insulating layers and the slit structure, and a third portion extending in a horizontal direction to connect the first portion and the second portion to each other; and tunneling patterns located between the conductive layers and the channel layer, respectively, and separated from each other by the insulating layers.

In an embodiment, a semiconductor device may include: a gate structure including insulating layers and conductive layers that are alternately stacked; a channel layer extending through the gate structure; first tunneling patterns located between the conductive layers and the channel layer, respectively; and second tunneling patterns located between the insulating layers and the channel layer, respectively, wherein regions where a concentration of nitrogen is higher than a concentration of oxygen in the first tunneling patterns and the second tunneling patterns may be different from each other.

In an embodiment, a manufacturing method of a semiconductor device may include: forming a stack by alternately stacking first sacrificial layers and second sacrificial layers; forming a channel hole in the stack; forming a tunneling layer in the channel hole; forming a channel layer in the tunneling layer; forming a slit extending through the stack; forming first openings by removing the first sacrificial layers through the slit, the first openings exposing the tunneling layer; forming first tunneling patterns by etching the tunneling layer through the first openings; forming insulating layers in the first openings; forming second openings by removing the second sacrificial layers through the slit, the second openings exposing the first tunneling patterns; forming a data storage layer along inner surfaces of the slit and the second openings; and forming conductive layers in the second openings.

In an embodiment, a manufacturing method of a semiconductor device may include: forming a stack by alternately stacking first sacrificial layers and second sacrificial layers; forming a channel hole in the stack; forming a tunneling layer in the channel hole; forming a channel layer in the tunneling layer; forming a slit extending through the stack; forming first openings by removing the first sacrificial layers through the slit, the first openings exposing the tunneling layer; forming insulating layers in the first openings; forming second openings by removing the second sacrificial layers through the slit, the second openings exposing the tunneling layer; injecting nitrogen into the tunneling layer through the second openings; and forming conductive layers in the second openings.

### BRIEF DESCRIPTION OF THE DRAWINGS

FIGS. 1A, 1B, and 1C are diagrams for describing a semiconductor device in accordance with an embodiment.

FIGS. 2A and 2B are diagrams for describing a semiconductor device in accordance with an embodiment.

FIGS. 3A and 3B are diagrams for describing a semiconductor device in accordance with an embodiment.

FIGS. 4A, 4B, 4C, 4D, and 4E are diagrams for describing an effect of a semiconductor device in accordance with an embodiment.

FIGS. 5A, 5B, 5C, 5D, 5E, and 5F are diagrams for describing a manufacturing method of a semiconductor device in accordance with an embodiment.

FIGS. 6A, 6B, and 6C are diagrams for describing a manufacturing method of a semiconductor device in accordance with an embodiment.

FIGS. 7A and 7B are diagrams for describing a manufacturing method of a semiconductor device in accordance with an embodiment.

FIGS. 8A, 8B, and 8C are diagrams for describing a manufacturing method of a semiconductor device in accordance with an embodiment.

FIG. 9 is a diagram for describing a semiconductor device in accordance with an embodiment.

FIG. 10 is a configuration diagram of a semiconductor device in accordance with an embodiment.

FIG. 11 is a configuration diagram of a semiconductor device in accordance with an embodiment.

### DETAILED DESCRIPTION

Various embodiments are directed to a semiconductor device having a stable structure and improved characteristics and a manufacturing method of the semiconductor device.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

According to an embodiment of the present technology, it is possible to provide a semiconductor device having a stable structure and improved reliability.

Hereafter, embodiments in accordance with the technical spirit of the present disclosure will be described with reference to the accompanying drawings.

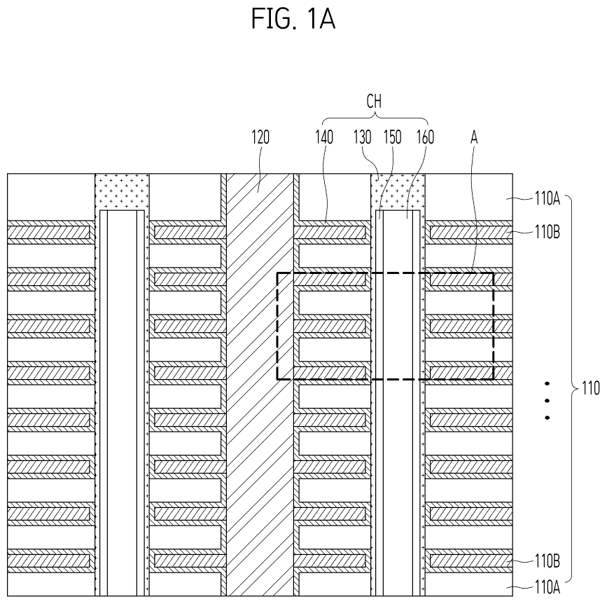

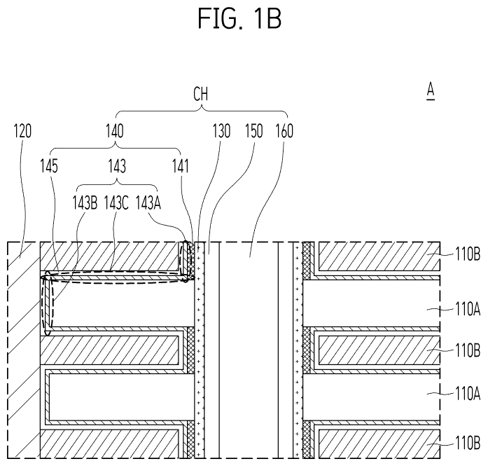

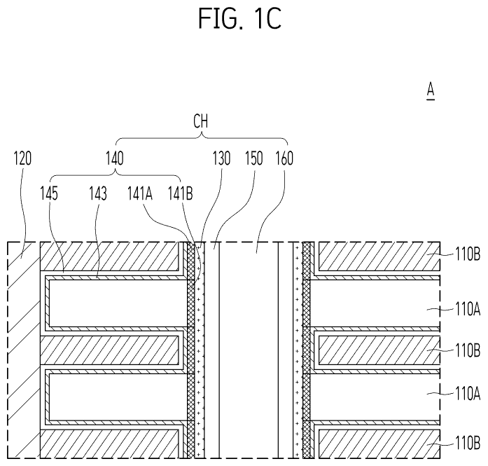

FIGS. 1A to 1C are diagrams for describing a semiconductor device in accordance with an embodiment. FIG. 1A is a cross-sectional view, and FIGS. 1B and 1C are enlarged views of portion A of FIG. 1A.

Referring to FIGS. 1A and 1B, the semiconductor device may include a gate structure 110, channel structures CH, and a slit structure 120.

The gate structure 110 may include insulating layers 110A and conductive layers 110B that are alternately stacked. The conductive layers 110B may be gate lines such as source select lines, word lines, or drain select lines. Source select transistors, memory cells, or drain select transistors may be located in regions where the channel structures CH and the conductive layers 110B intersect each other. For example, at least one source select transistor, a plurality of memory cells, and at least one drain select transistor that are stacked along the channel structure CH may constitute one memory string. The insulating layers 110A may each include an insulating material such as oxide. The conductive layers 110B may each include a conductive material such as tungsten, molybdenum, or polysilicon.

The slit structure 120 may extend through the gate structure 110. For example, the slit structure 120 may penetrate through the gate structure 110. The slit structure 120 may be used as a passage for forming the gate structure 110, the channel structures CH, or the like, in a process of manufacturing the semiconductor device. The slit structure 120 may include an insulating material, a conductive material, or a semiconductor material.

The channel structures CH may extend through the gate structure 110. Each of the channel structures CH may include at least one of a channel layer 130, a memory layer 140, a first insulating core 150, and a second insulating core 160.

The channel layer 130 may extend through the gate structure 110. For example, the channel layer 130 may penetrate through the gate structure 110. The channel layer 130 may include a semiconductor material. For example, the channel layer 130 may include polysilicon, germanium, or the like.

In an embodiment, grain boundaries may exist in the channel layer 130, and when there are many grain boundaries, the mobility of charges in the channel layer 130 may be decreased. According to an embodiment of the present disclosure, the channel layer 130 may include at least one of hydrogen and deuterium. Hydrogen or deuterium may be injected into the channel layer 130 in the process of manufacturing the semiconductor device, and may be trapped at trap sites of the grain boundaries existing in the channel layer 130. In such a case, the layer quality of the channel layer 130, in an embodiment, may be improved, and the mobility of the charges, in an embodiment, may be increased.

The memory layer 140 may include tunneling patterns 141, a data storage layer 143, and a blocking layer 145. The tunneling patterns 141 may be located between the conductive layers 110B and the channel layer 130, respectively. The tunneling patterns 141 may be spaced apart from each other in a vertical direction. Here, the vertical direction may be a direction parallel to a stacking direction of the insulating layers 110A and the conductive layers 110B of the gate structure 110. For example, the tunneling patterns 141 may be separated from each other by the insulating layers 110A.

The tunneling patterns 141 may be used as passages through which the charges in the channel layer 130 are tunneled to the data storage layer 143 when a bias is applied to the conductive layers 110B. Here, an energy band gap of the tunneling patterns 141 may be adjusted by adjusting a composition of a material included in the tunneling patterns 141. The tunneling patterns 141 may each include nitrogen. For example, the tunneling patterns 141 may each include nitrogen oxide. When the tunneling patterns 141 each include nitrogen oxide, the energy band gap of the tunneling patterns 141 may be smaller than when the tunneling patterns 141 each include only oxide. In such a case, even though a relatively small bias is applied to the conductive layers 110B, the charges in the channel layer 130 may be tunneled to the data storage layer 143 through the tunneling patterns 141. Accordingly, in an embodiment, an operation voltage of the memory cell may be reduced, and, in an embodiment, a larger number of memory cells may be stacked.

In addition, an amount of charges tunneled from the channel layer 130 to the data storage layer 143 may be adjusted by adjusting the composition of the material included in the tunneling patterns 141. According to an embodiment of the present disclosure, the tunneling patterns 141 may each include SiOₓN_{y} (0<x<1 and 0<y<1). Here, the tunneling patterns 141 may each have a concentration of nitrogen higher than a concentration of oxygen in a middle region of each of the tunneling patterns 141, and may each have a concentration of nitrogen lower than a concentration of oxygen in a region of each of the tunneling patterns 141 adjacent to the channel layer 130 and a region of each of the tunneling patterns 141 adjacent to the conductive layers 110B. For example, when a region of each of the tunneling patterns 141 is evenly divided into three regions, the region of each of the tunneling patterns 141 adjacent to the channel layer 130 may be a first region, the region of each of the tunneling patterns 141 adjacent to the conductive layers 110B may be a second region, and the middle region of each of the tunneling patterns 141 between the first region and the second region may be a third region. In other words, a concentration of nitrogen may be higher than a concentration of oxygen in the third region, and a concentration of nitrogen may be lower than a concentration of oxygen in the first region and the second region. In such a case, an amount of charges tunneled to the data storage layer 143 may increase. Accordingly, in an embodiment, a data storage capability of the data storage layer 143 may be improved.

The data storage layer 143 may be located between the slit structure 120 and the channel layer 130. The data storage layer 143 may include a first portion 143A, a second portion 143B, and a third portion 143C. The first portion 143A may be located between each of the conductive layers 110B and the channel layer 130. The second portion 143B may be located between each of the insulating layers 110A and the slit structure 120. The third portion 143C may extend in a horizontal direction to connect the first portion 143A and the second portion 143B to each other. Here, the horizontal direction may be a direction parallel to a direction in which the insulating layers 110A and the conductive layers 110B of the gate structure 110 extend. The data storage layer 143 may include silicon nitride. For example, the data storage layer 143 may include Si₃N₄.

The charges may be trapped in the data storage layer 143, and data may be stored in the form of bits. According to the related art, a data storage layer may have a shape in which it surrounds sidewalls of a channel layer, and data storage layers of stacked memory cells may be connected to each other. In an embodiment, when an interval between conductive layers of a gate structure is reduced in order to improve the degree of integration of a semiconductor device, charges may move between the stacked memory cells. Accordingly, in an embodiment, reliability of the memory cell may decrease.

According to an embodiment of the present disclosure, the data storage layer 143 may include the first portions 143A located between the conductive layers 110B and the channel layer 130. The data storage layer 143 might not exist between the insulating layers 110A and the channel layer 130. In other words, the data storage layer 143 may include the first portions 143A spaced apart from each other in the vertical direction. In such an embodiment, it is possible to prevent or reduce a phenomenon in which charges trapped in one conductive layer 110B and the first portion 143A spread to an adjacent region. Accordingly, in an embodiment, the reliability of the memory cell may increase.

The blocking layer 145 may be located between the slit structure 120 and the data storage layer 143. For example, the blocking layer 145 may extend along a profile of the data storage layer 143. The blocking layer 145 may prevent or mitigate the charges from moving between the data storage layer 143 and the conductive layers 110B. The blocking layer 145 may include silicon oxide. For example, the blocking layer 145 may include SiO₂. Alternatively, the blocking layer 145 may include a material having a high dielectric constant. The blocking layer 145 may include at least one of aluminum oxide, hafnium oxide, and zirconium oxide. For example, the blocking layer 145 may include at least one of Al₂O₃, HfO₂, and ZrO₂.

The first insulating core 150 may extend through the gate structure 110. The first insulating core 150 may be located in the channel layer 130. In an embodiment, the first insulating core 150 may be used to increase the mobility of the charges in the channel layer 130 in the process of manufacturing the semiconductor device. The first insulating core 150 may include nitride. For example, the first insulating core 150 may include silicon nitride.

The second insulating core 160 may extend through the gate structure 110. The second insulating core 160 may be located in the first insulating core 150. In an embodiment, the second insulating core 160 may improve the prevention or mitigation of the warpage of a wafer. The second insulating core 160 may include a material having a stress different from that of the first insulating core 150. The second insulating core 160 may include oxide. For example, the second insulating core 160 may include at least one of Al₂O₃, HfO₂, and ZrO₂.

When the first insulating core 150 includes nitride, the first insulating core 150 may act as compressive stress on the wafer. When the second insulating core 160 includes oxide, the second insulating core 160 may act as tensile stress on the wafer. Accordingly, in an embodiment, the compressive stress of the first insulating core 150 and the tensile stress of the second insulating core 160 may be offset, and the ability to prevent or mitigate the warpage of the wafer may be improved.

Referring to FIG. 1C, the semiconductor device may include first tunneling patterns 141A and second tunneling patterns 141B. The first tunneling patterns 141A may be located between the conductive layers 110B and the channel layer 130, respectively, and the second tunneling patterns 141B may be located between the insulating layers 110A and the channel layer 130, respectively. Here, the first tunneling patterns 141A and the second tunneling patterns 141B may be used as one tunneling layer.

The first tunneling patterns 141A may each include nitrogen oxide. For example, the first tunneling patterns 141A may each include SiOₓN_{y} (0<x<1 and 0<y<1). The second tunneling patterns 141B may each include oxide. For example, the second tunneling patterns 141B may each include SiO₂. Alternatively, the second tunneling patterns 141B may each include nitrogen oxide. For example, the second tunneling patterns 141B may each include SiOₓN_{y} (0<x<1 and 0<y<1).

According to an embodiment of the present disclosure, when the first tunneling patterns 141A each include nitrogen oxide, a concentration of nitrogen may be higher than a concentration of oxygen in a middle region of each of the first tunneling patterns 141A, and a concentration of nitrogen may be lower than a concentration of oxygen in a region of each of the first tunneling patterns 141A adjacent to the channel layer 130 and a region of each of the first tunneling patterns 141A adjacent to the conductive layers 110B. When the second tunneling patterns 141B each include nitrogen oxide, a concentration of nitrogen may be higher than a concentration of oxygen in a region of each of the second tunneling patterns 141B adjacent to the channel layer 130, and a concentration of nitrogen may be lower than a concentration of oxygen a region of each of the second tunneling patterns 141B adjacent to the insulating layers 110A.

In such a case, an amount of charges tunneled from the channel layer 130 to the data storage layer 143 through the first tunneling patterns 141A may increase, and an amount of charges tunneled from the channel layer 130 to the data storage layer 143 through the second tunneling patterns 141B may decrease. Accordingly, in an embodiment, an amount of charges tunneled in regions of the memory cells may be increased, and an amount of charges tunneled in regions other than the memory cells may be decreased, such that it is possible to improve the data storage capability of the data storage layer 143.

According to the structure described above, the channel layer 130 may include at least one of hydrogen and deuterium. In such a case, hydrogen or deuterium may be trapped at trap sites of grain boundaries in the channel layer 130. Accordingly, in an embodiment, the layer quality of the channel layer 130 may be improved, and the mobility of the charges may be increased.

The tunneling patterns 141 may each include nitrogen oxide. In such a case, in an embodiment, it is possible to reduce the operation voltage of the memory cell by making the energy band gap of the tunneling patterns 141 small, and it is possible to improve the data storage capability of the data storage layer 143 by increasing the amount of charges tunneled to the data storage layer 143.

In addition, the data storage layer 143 may have the first portions 143A spaced apart from each other in the vertical direction. In such a case, in an embodiment, it is possible to prevent or reduce a phenomenon in which the charges trapped in one conductive layer 110B and the first portion 143A spread to an adjacent region, and it is possible to improve the reliability of the memory cell.

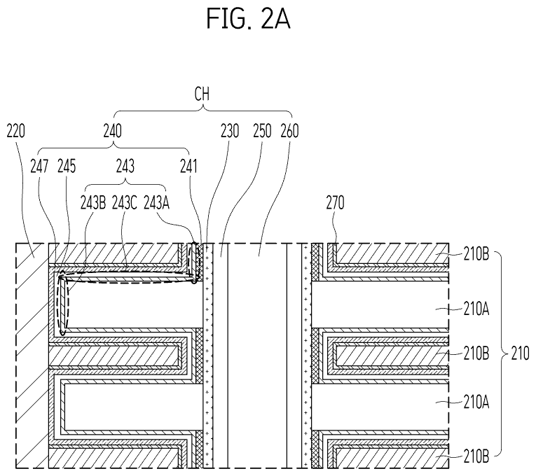

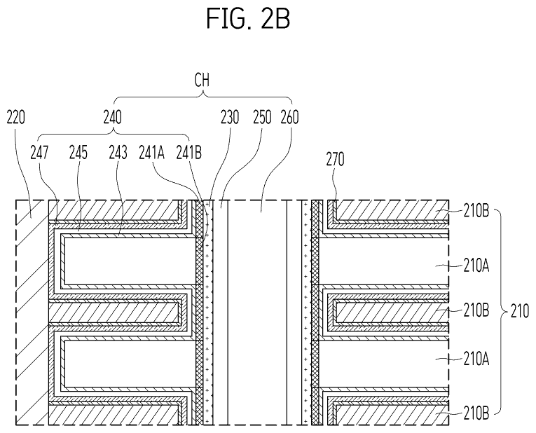

FIGS. 2A and 2B are diagrams for describing a semiconductor device in accordance with an embodiment. Hereinafter, the content overlapping with the previously described content will be omitted.

Referring to FIG. 2A, the semiconductor device may include a gate structure 210, channel structures CH, a slit structure 220, and barrier patterns 270.

The gate structure 210 may include insulating layers 210A and conductive layers 210B that are alternately stacked. The insulating layers 210A may each include an insulating material such as oxide. The conductive layers 210B may each include a conductive material such as tungsten, molybdenum, or polysilicon.

The slit structure 220 may extend through the gate structure 210. The slit structure 220 may be used as a passage for forming the gate structure 210, the channel structures CH, or the like, in a process of manufacturing the semiconductor device. The slit structure 220 may include an insulating material, a conductive material, or a semiconductor material.

The channel structures CH may extend through the gate structure 210. Each of the channel structures CH may include at least one of a channel layer 230, a memory layer 240, a first insulating core 250, and a second insulating core 260.

The channel layer 230 may extend through the gate structure 210. The channel layer 230 may include a semiconductor material. For example, the channel layer 230 may include polysilicon, germanium, or the like.

According to an embodiment of the present disclosure, the channel layer 230 may include hydrogen or deuterium. Hydrogen or deuterium may be injected into the channel layer 230 in the process of manufacturing the semiconductor device, and may be trapped at trap sites of grain boundaries existing in the channel layer 230. In such a case, in an embodiment, the layer quality of the channel layer 230 may be improved, and the mobility of charges may be increased.

The memory layer 240 may include tunneling patterns 241, a data storage layer 243, a first blocking layer 245, and a second blocking layer 247. The tunneling patterns 241 may be spaced apart from each other in the vertical direction. Here, the vertical direction may be a direction parallel to a stacking direction of the insulating layers 210A and the conductive layers 210B of the gate structure 210.

The tunneling patterns 241 may each include nitrogen oxide. When the tunneling patterns 241 each include nitrogen oxide, an energy band gap of the tunneling patterns 241 may be smaller than when the tunneling patterns 241 each include only oxide, and even though a relatively small bias is applied, charges in the channel layer 230 may be tunneled to the data storage layer 243. Accordingly, in an embodiment, an operation voltage of a memory cell may be reduced, and a larger number of memory cells may be stacked.

In addition, the tunneling patterns 241 may each include SiOₓN_{y} (0<x<1 and 0<y<1). The tunneling patterns 241 may each have a concentration of nitrogen higher than a concentration of oxygen in a middle region of each of the tunneling patterns 241. In such a case, an amount of charges tunneled in a region adjacent to the channel layer 230 may increase, and an amount of charges tunneled to the data storage layer 243 may increase. Accordingly, in an embodiment, a data storage capability of the data storage layer 243 may be improved.

The data storage layer 243 may be located between the slit structure 220 and the channel layer 230. The data storage layer 243 may include a first portion 243A, a second portion 243B, and a third portion 243C. The first portion 243A may be located between each of the conductive layers 210B and the channel layer 230. The second portion 243B may be located between each of the insulating layers 210A and the slit structure 220. The third portion 243C may extend in the horizontal direction to connect the first portion 243A and the second portion 243B to each other. Here, the horizontal direction may be a direction parallel to a direction in which the insulating layers 210A and the conductive layers 210B of the gate structure 210 extend. The data storage layer 243 may include silicon nitride. For example, the data storage layer 243 may include Si₃N₄.

The charges may be trapped in the data storage layer 243, and data may be stored in the form of bits. The data storage layer 243 may include the first portions 243A located between the conductive layers 210B and the channel layer 230. In other words, the data storage layer 243 may include the first portions 243A spaced apart from each other in the vertical direction. In such a case, in an embodiment, it is possible to prevent or reduce a phenomenon in which charges trapped in one conductive layer 210B and the first portion 243A spread to an adjacent region. Accordingly, in an embodiment, the reliability of the memory cell may increase.

The first blocking layer 245 may be located between the slit structure 220 and the data storage layer 243. For example, the first blocking layer 245 may extend along a profile of the data storage layer 243. The first blocking layer 245 may include silicon oxide. For example, the first blocking layer 245 may include SiO₂.

The second blocking layer 247 may be located between the slit structure 220 and the first blocking layer 245. For example, the second blocking layer 247 may extend along a profile of the first blocking layer 245. The second blocking layer 247 may include a material having a higher dielectric constant than the first blocking layer 245. For example, the second blocking layer 247 may include at least one of aluminum oxide, hafnium oxide, and zirconium oxide. The second blocking layer 247 may include at least one of Al₂O₃, HfO₂, and ZrO₂.

During an erase operation of the memory cell, charges of the conductive layers 210B may be back-tunneled to the data storage layer 243. In such a case, the charges trapped in the data storage layer 243 might not be detrapped due to the back-tunneled charges. In an embodiment, when an operation of the memory cell is repeated in such a state, endurance of the memory cell may be weakened.

According to an embodiment of the present disclosure, the first blocking layer 245 and the second blocking layer 247 may prevent or reduce a phenomenon in which the charges of the conductive layers 210B are back-tunneled to the data storage layer 243. For example, in an embodiment, by additionally forming the second blocking layer 247 in addition to the first blocking layer 245 to increase a thickness of the blocking layers 245 and 247 through which the back-tunneled charges should tunnel, it is possible to reduce a back-tunneling phenomenon. In addition, in an embodiment, when the second blocking layer 247 includes the material having the higher dielectric constant than the first blocking layer 245, energy required for the charges of the conductive layers 210B to be tunneled through the second blocking layer 247 may increase, and it is possible to prevent or mitigate the charges from being back-tunneled.

The barrier patterns 270 may be located between the conductive layers 210B and the second blocking layer 247. The barrier patterns 270 may surround the conductive layers 210B. Here, the barrier pattern 270 and the conductive layer 210B may be used as a gate line. The barrier patterns 270 may each include metal nitride. For example, the barrier patterns 270 may each include metal nitride, and may each include at least one of TaN and WN.

In an embodiment, the barrier patterns 270 may be used to increase bonding strength of the conductive layers 210B in the process of forming the semiconductor device. In addition, in an embodiment, the barrier patterns 270 may prevent or reduce a phenomenon in which the charges of the conductive layers 210B are back-tunneled to the data storage layer 243. In an embodiment, the barrier patterns 270 may increase a magnitude of a work function required for the charges of the conductive layers 210B to be back-tunneled. For example, when the conductive layers 210B and the barrier patterns 270 including at least one of TaN and WN are bonded to each other, the magnitude of the work function required for the charges of the conductive layers 210B to be back-tunneled may be increased compared to when the conductive layers 210B and barrier patterns including TiN are bonded to each other. In such a case, in an embodiment, energy required for back-tunneling may increase, and it is possible to prevent or mitigate the charges from being back-tunneled.

The first insulating core 250 may be located in the channel layer 230. In an embodiment, the first insulating core 250 may be used to increase the mobility of the charges in the channel layer 230 in the process of manufacturing the semiconductor device. The first insulating core 250 may include nitride. For example, the first insulating core 250 may include silicon nitride.

The second insulating core 260 may be located in the first insulating core 250. The second insulating core 260 may include a material having stress different from that of the first insulating core 250. The second insulating core 260 may include oxide. For example, the second insulating core 260 may include at least one of Al₂O₃, HfO₂, and ZrO₂. Accordingly, in an embodiment, compressive stress of the first insulating core 250 and tensile stress of the second insulating core 260 may be offset, and the ability to prevent or mitigate the warpage of a wafer may be improved.

Referring to FIG. 2B, the semiconductor device may include first tunneling patterns 241A and second tunneling patterns 241B. Here, the first tunneling patterns 241A and the second tunneling patterns 241B may be used as one tunneling layer.

The first tunneling patterns 241A may each include SiOₓN_{y} (0<x<1 and 0<y<1). The second tunneling patterns 241B may each include silicon oxide. For example, the second tunneling patterns 241B may each include SiO₂. Alternatively, the second tunneling patterns 241B may each include SiOₓN_{y} (0<x<1 and 0<y<1). In such a case, in an embodiment, an amount of charges tunneled from the channel layer 230 to the data storage layer 243 through the first tunneling patterns 241A may increase, and an amount of charges tunneled from the channel layer 230 to the data storage layer 243 through the second tunneling patterns 241B may decrease. Accordingly, in an embodiment, a data storage capability of the data storage layer 243 may be improved.

According to the structure described above, the semiconductor device may include the first blocking layer 245 and the second blocking layer 247. In such a case, in an embodiment, it is possible to prevent or reduce the phenomenon in which the charges of the conductive layers 210B are back-tunneled to the data storage layer 243.

In addition, the semiconductor device may include the barrier patterns 270. In an embodiment, the barrier patterns 270 may include at least one of TaN and WN, and may be bonded to the conductive layers 210B to increase the magnitude of the work function required for the charges of the conductive layers 210B to be back-tunneled, and accordingly prevent or mitigate the charges from being back-tunneled.

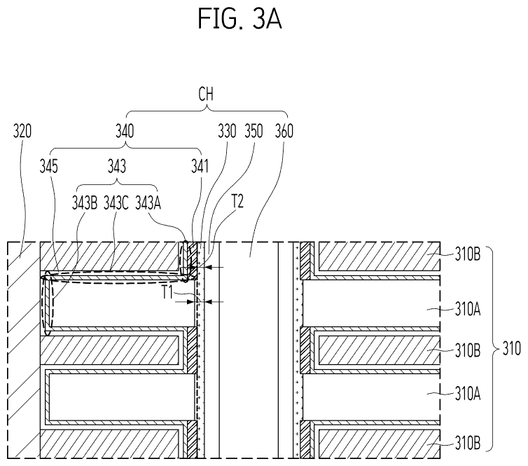

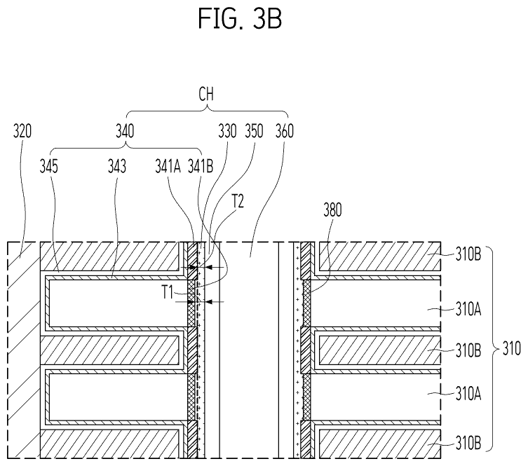

FIGS. 3A and 3B are diagrams for describing a semiconductor device in accordance with an embodiment. Hereinafter, the content overlapping with the previously described content will be omitted.

Referring to FIG. 3A, a gate structure 310 may include insulating layers 310A and conductive layers 310B that are alternately stacked. The insulating layers 310A may each include an insulating material such as oxide. The conductive layers 310B may each include a conductive material such as tungsten, molybdenum, or polysilicon.

The slit structure 320 may extend through the gate structure 310. The slit structure 320 may be used as a passage for forming the gate structure 310, the channel structures CH, or the like, in a process of manufacturing the semiconductor device. The slit structure 320 may include an insulating material, a conductive material, or a semiconductor material.

The channel structures CH may extend through the gate structure 310. Each of the channel structures CH may include at least one of a channel layer 330, a memory layer 340, a first insulating core 350, and a second insulating core 360.

The channel layer 330 may extend through the gate structure 310. The channel layer 330 may have a first thickness T1 at a level corresponding to the insulating layers 310A, and may have a second thickness T2 smaller than the first thickness T1 at a level corresponding to the conductive layers 310B. The channel layer 330 may include a semiconductor material. For example, the channel layer 330 may include polysilicon, germanium, or the like.

According to an embodiment of the present disclosure, the channel layer 330 may include hydrogen or deuterium. In such a case, in an embodiment, the layer quality of the channel layer 330 may be improved, and the mobility of charges may be increased.

The memory layer 340 may include tunneling patterns 341, a data storage layer 343, and a blocking layer 345. The tunneling patterns 341 may be spaced apart from each other in the vertical direction.

The tunneling patterns 341 may be formed by oxidizing the channel layer 330 in the process of manufacturing the semiconductor device. For example, the tunneling patterns 341 may be formed in the form of silicon oxide by oxidizing polysilicon of the channel layer 330. The tunneling patterns 341 may each be formed of SiO₂. In such a case, the tunneling patterns 341 may have a shape in which they protrude into the channel layer 330. Subsequently, the tunneling patterns 341 including nitrogen oxide may be formed by injecting nitrogen. Here, nitrogen oxide may be SiOₓN_{y}.

When tunneling patterns are formed by a deposition method, the tunneling patterns may each be formed of SiO₂ having many impurities. For example, the tunneling patterns may each be formed of SiO₂ having a form in which not only Si and O are bonded to each other, but also Si and impurities such as a deposition gas are bonded to each other. In an embodiment, when a memory cell is repeatedly operated in such a state, an amount of charges tunneled through the tunneling patterns might not be constant, and the reliability of the memory cell may be reduced.

According to an embodiment of the present disclosure, the tunneling patterns 341 may each be formed of SiO₂ obtained by oxidizing the channel layer 330. In such a case, in an embodiment, the tunneling patterns may each be formed of SiO₂ having relatively fewer impurities than when the tunneling patterns are formed by the deposition method. Accordingly, in an embodiment, by keeping an amount of charges tunneled through the tunneling patterns constant even though the memory cell is repeatedly operated, it is possible to improve the reliability of the memory cell.

The data storage layer 343 may be located between the slit structure 320 and the channel layer 330. The data storage layer 343 may include a first portion 343A, a second portion 343B, and a third portion 343C. The first portion 343A may be located between each of the conductive layers 310B and the channel layer 330. The second portion 343B may be located between each of the insulating layers 310A and the slit structure 320. The third portion 343C may extend in the horizontal direction to connect the first portion 343A and the second portion 343B to each other. The data storage layer 343 may include silicon nitride. For example, the data storage layer 343 may include Si₃N₄.

The charges may be trapped in the data storage layer 343, and data may be stored in the form of bits. The data storage layer 343 may include the first portions 343A spaced apart from each other in the vertical direction. In such a case, in an embodiment, it is possible to prevent or reduce a phenomenon in which charges trapped in one conductive layer 310B and the first portion 343A spread to an adjacent region. Accordingly, in an embodiment, the reliability of the memory cell may increase.

The blocking layer 345 may be located between the slit structure 320 and the data storage layer 343. In an embodiment, the blocking layer 345 may prevent or mitigate the charges from moving between the data storage layer 343 and the conductive layers 310B. The blocking layer 345 may include silicon oxide. For example, the blocking layer 345 may include SiO₂. Alternatively, the blocking layer 345 may include a material having a high dielectric constant. For example, the blocking layer 345 may include at least one of aluminum oxide, hafnium oxide, and zirconium oxide. The blocking layer 345 may include at least one of Al₂O₃, HfO₂, and ZrO₂.

The first insulating core 350 may be located in the channel layer 330. In an embodiment, the first insulating core 350 may be used to increase the mobility of the charges in the channel layer 330 in the process of manufacturing the semiconductor device. The first insulating core 350 may include nitride. For example, the first insulating core 350 may include silicon nitride.

The second insulating core 360 may be located in the first insulating core 350. The second insulating core 360 may include a material having stress different from that of the first insulating core 350. The second insulating core 360 may include oxide. For example, the second insulating core 360 may include at least one of Al₂O₃, HfO₂, and ZrO₂. In such a case, compressive stress of the first insulating core 350 and tensile stress of the second insulating core 360 may be offset, and the ability to prevent or mitigate the warpage of a wafer may be improved.

Referring to FIG. 3B, the semiconductor device may include first tunneling patterns 341A and second tunneling patterns 341B. Here, the first tunneling patterns 341A and the second tunneling patterns 341B may be used as one tunneling layer. However, the first tunneling patterns 341A and the second tunneling patterns 341B may have different thicknesses.

The first tunneling patterns 341A may each include SiOₓN_{y} (0<x<1 and 0<y<1). The second tunneling patterns 341B may each include silicon oxide. For example, the second tunneling patterns 341B may each include SiO₂. Alternatively, the second tunneling patterns 341B may each include SiOₓN_{y} (0<x<1 and 0<y<1). In such a case, in an embodiment, an amount of charges tunneled from the channel layer 330 to the data storage layer 343 through the first tunneling patterns 341A may increase, and an amount of charges tunneled from the channel layer 330 to the data storage layer 243 through the second tunneling patterns 341B may decrease. Accordingly, in an embodiment, a data storage capability of the data storage layer 343 may be improved.

According to the structure described above, the semiconductor device may include the first tunneling patterns 341A formed by oxidizing the channel layer 330. In such a case, in an embodiment, the reliability of the memory cell may be improved compared to when the tunneling patterns are formed by the deposition method.

In addition, the semiconductor device may include the second tunneling patterns 341B remaining without being removed in the process of manufacturing the semiconductor device. The first tunneling patterns 341A may each have a concentration of nitrogen higher than a concentration of oxygen in a region of each of the first tunneling patterns 341A adjacent to the channel layer 330, and the second tunneling patterns 341B may each have a concentration of nitrogen lower than a concentration of oxygen in a region of each of the second tunneling patterns 341B adjacent to the channel layer 330. In such a case, in an embodiment, an amount of charges tunneled from the channel layer 330 to the data storage layer 343 through the first tunneling patterns 341A may increase, and an amount of charges tunneled from the channel layer 330 to the data storage layer 343 through the second tunneling patterns 341B may decrease. Accordingly, in an embodiment, an amount of charges tunneled in regions of the memory cells may be increased, and an amount of charges tunneled in regions other than the memory cells may be decreased, such that it is possible to improve the data storage capability of the data storage layer 343.

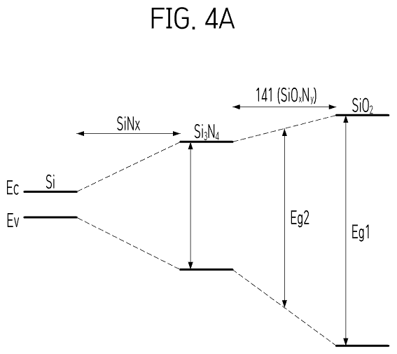

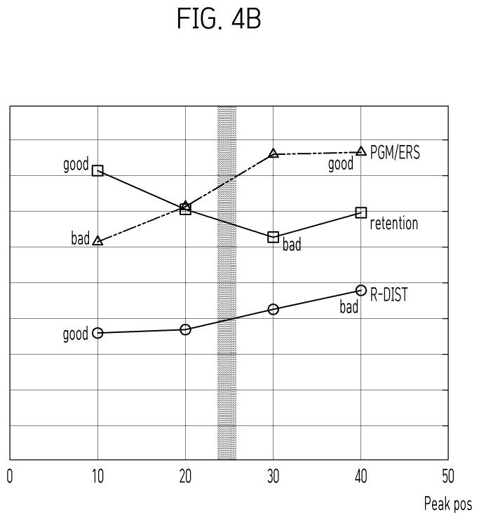

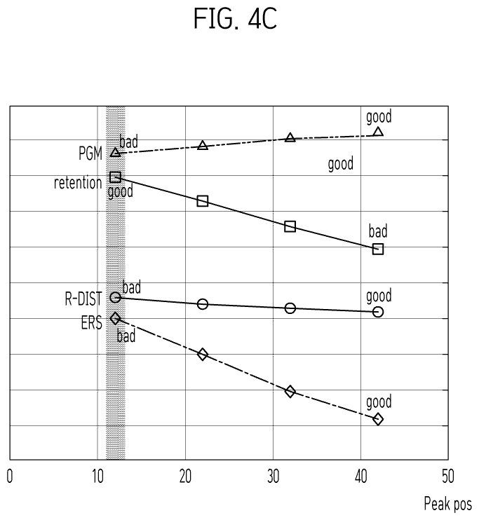

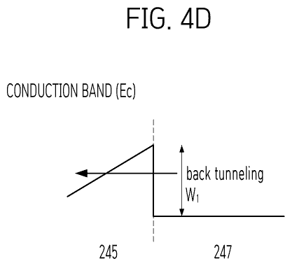

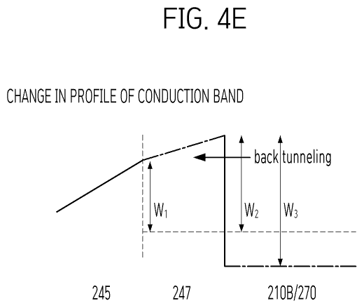

FIGS. 4A to 4E are diagrams for describing an effect of a semiconductor device in accordance with an embodiment. Hereinafter, the content overlapping with the previously described content will be omitted.

FIG. 4A is a diagram for describing an energy band gap Eg of a material. Materials may each include a conduction band E_{c}, which is an empty energy region of an upper portion where electrons do not exist, and a valence band Eᵥ, which is an energy region full of charges. Here, an energy difference between the conduction band E_{c} and the valence band Eᵥ may be referred to as the energy band gap Eg. In order for charges to be tunneled through tunneling patterns, a bias greater than the energy band gap Eg should be applied.

Referring to FIG. 1B again, when the tunneling patterns each include silicon oxide (SiO₂), a bias higher than or equal to a first energy band gap Eg1 should be applied in order to tunnel the charges through the tunneling patterns. According to an embodiment of the present disclosure, the tunneling patterns 141 (SiOₓN_{y}) may each include nitrogen oxide, and only a bias higher than or equal to a second energy band gap Eg2 smaller than the first energy band gap Eg1 needs to be applied in order to tunnel the charges through the tunneling patterns 141. Accordingly, an operation voltage of a memory cell may be reduced, and more memory cells may be stacked.

FIGS. 4B and 4C are drawings for describing differences in concentration of nitrogen according to positions in the tunneling patterns 141A and 141B of FIG. 1C. FIG. 4B is a drawing about the first tunneling patterns 141A of regions corresponding to the conductive layers 110B, and FIG. 4C is a drawing about the second tunneling patterns 141B of regions corresponding to the insulating layers 110A. Here, “peak pos” may refer to a position (peak position) where a concentration of nitrogen is the highest, and each number may refer to a distance unit based on the channel layer 130 of FIGS. 1A and 1C. For example, “10” may refer to a position adjacent to the channel layer 130 compared to “40”. Here, the unit may be “angstrom (Å)”.

Referring to FIGS. 1C and 4B, it can be seen that program (PGM) and erase (ERS) (i.e., PGM/ERS) operation speeds of the memory cell are improved from a case (peak pos 10) in which a concentration of nitrogen is the highest in a region where the first tunneling pattern 141A is adjacent to the channel layer 130 toward a case (peak pos 40) in which a concentration of nitrogen is the highest in a region where the first tunneling pattern 141A is spaced apart from the channel layer 130. In other words, when a region where the concentration of nitrogen is the highest in the first tunneling pattern 141A is a region adjacent to the data storage layer 143 or the conductive layers 110B, a movement speed of charges tunneled from the channel layer 130 to the first tunneling pattern 141A may increase, and an amount of the charges tunneled from the channel layer 130 to the first tunneling pattern 141A may increase.

In addition, it can be seen that a charge retention period (retention) of the memory cell decreases from the case (peak pos 10) in which the concentration of nitrogen is the highest in the region where the first tunneling pattern 141A is adjacent to the channel layer 130 toward the case (peak pos 40) in which the concentration of nitrogen is the highest in the region where the first tunneling pattern 141A is spaced apart from the channel layer 130 and then increases again in the vicinity of “peak pos 30”.

In addition, it can be seen that a read-disturb (R-DIST) capability of the memory cell decreases from the case (peak pos 10) in which the concentration of nitrogen is the highest in the region where the first tunneling pattern 141A is adjacent to the channel layer 130 toward the case (peak pos 40) in which the concentration of nitrogen is the highest in the region where the first tunneling pattern 141A is spaced apart from the channel layer 130.

In terms of the charge retention period of the memory cell and the read-disturb capability of the memory cell, it is preferable that the concentration of nitrogen is the greatest in the region where the first tunneling pattern 141A is adjacent to the channel layer 130. However, in such a case, the program and erase operation speeds of the memory cell may be slow.

Similarly, in terms of the program and erase operation speeds of the memory cell, it is preferable that the concentration of nitrogen is the highest in the region where the first tunneling pattern 141A is spaced apart from the channel layer 130. However, in such a case, the charge retention period of the memory cell and the read-disturb capability of the memory cell may be reduced. Accordingly, it is necessary to select the region where the concentration of nitrogen is the highest in the first tunneling pattern 141A in consideration of all of the above factors.

According to an embodiment of the present disclosure, the concentration of nitrogen may be higher than the concentration of oxygen in the middle region of the first tunneling pattern 141A. In other words, the concentration of nitrogen may be the highest in the middle region of the first tunneling pattern 141A. Here, the middle region may refer to a region between a region adjacent to the channel layer 130 and a region spaced apart from the channel layer 130. For example, referring to FIG. 4B again, the concentration of nitrogen may be higher than the concentration of oxygen in the vicinity of 25 A, which is an middle region between 10 A, which is a region where the first tunneling pattern 141A is most adjacent to the channel layer 130, and 40 A, which is a region where the first tunneling pattern 141A is most spaced apart from the channel layer 130. In such a case, it is possible to secure the charge retention period and the read-disturb capability of the memory cell as well as the program and erase operation speeds of the memory cell.

Referring to FIGS. 1C and 4C, it can be seen that program (PGM) and erase (ERS) operation speeds of the memory cell decrease from a case (peak pos 40) in which a concentration of nitrogen is the highest in a region where the second tunneling pattern 141B is spaced apart from the channel layer 130 toward a case (peak pos 10) in which a concentration of nitrogen is the highest in a region where the second tunneling pattern 141B is adjacent to the channel layer 130.

In addition, it can be seen that a charge retention period (retention) of the memory cell decreases from the case (peak pos 10) in which the concentration of nitrogen is the highest in the region where the second tunneling pattern 141B is adjacent to the channel layer 130 toward the case (peak pos 40) in which the concentration of nitrogen is the highest in the region where the second tunneling pattern 141B is spaced apart from the channel layer 130.

In addition, it can be seen that a read-disturb (R-DIST) capability of the memory cell is improved from the case (peak pos 10) in which the concentration of nitrogen is the highest in the region where the second tunneling pattern 141B is adjacent to the channel layer 130 toward the case (peak pos 40) in which the concentration of nitrogen is the highest in the region where the second tunneling pattern 141B is spaced apart from the channel layer 130.

Because the memory cells are formed in regions where the conductive layers 110B and the channel layer 130 intersect each other, in an embodiment, it is preferable for the second tunneling patterns 141B located in the regions corresponding to the insulating layers 110A to reduce the operation speeds so as not to interfere with program and erase operations of the memory cells.

According to an embodiment of the present disclosure, in the region where the second tunneling pattern 141B is adjacent to the channel layer 130, the concentration of nitrogen may be higher than the concentration of oxygen. In an embodiment, in the region where the second tunneling pattern 141B is spaced apart from the channel layer 130, the concentration of nitrogen may be lower than the concentration of oxygen. In such a case, in an embodiment, a speed of the charges tunneled through the second tunneling patterns 141B located in the regions corresponding to the insulating layers 110A may be slow, and an amount of the charges tunneled through the second tunneling patterns 141B may be decreased.

Referring to FIGS. 2A, 2B, and 4D, in order for the charges in the conductive layers 210B to be back-tunneled through the first blocking layer 245, energy greater than or equal to a first work function W₁ is required.

Referring to FIGS. 2A, 2B, and 4E, the semiconductor device includes the first blocking layer 245 and the second blocking layer 247. Here, the second blocking layer 247 includes a material having a high dielectric constant. For example, the second blocking layer 247 includes at least one of aluminum oxide, hafnium oxide, and zirconium oxide having a higher dielectric constant than the first blocking layer 245 (SiO₂). The second blocking layer 247 includes at least one of Al₂O₃, HfO₂, and ZrO₂. In such a case, energy required for the charges of the conductive layers 210B to be tunneled through the second blocking layer 247 increases. In other words, energy greater than or equal to second work function W₂ greater than the first work function W₁ is required.

In addition, the semiconductor device includes the barrier patterns 270 surrounding the conductive layers 210B (i.e., 210B/270). The barrier pattern 270 and the conductive layer 210B may be used as a gate line. The barrier patterns 270 may each include metal nitride, and may each include at least one of TaN and WN. In such a case, energy required for the charges of the conductive layers 210B to be back-tunneled increases. In other words, energy greater than or equal to third work function W₃ greater than the second work function W₂ is required.

Accordingly, according to an embodiment of the present disclosure, by increasing the work function required for the charges of the conductive layers 210B to be back-tunneled using the first blocking layer 245, the second blocking layer 247, and the barrier patterns 270, it is possible to prevent or mitigate a back tunneling phenomenon from occurring.

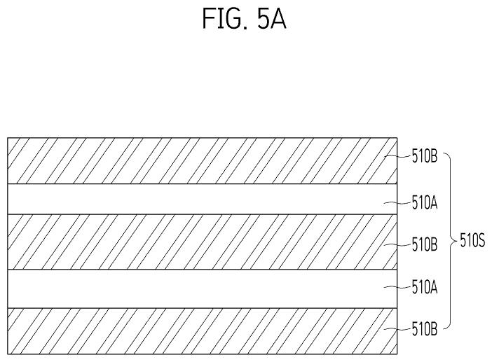

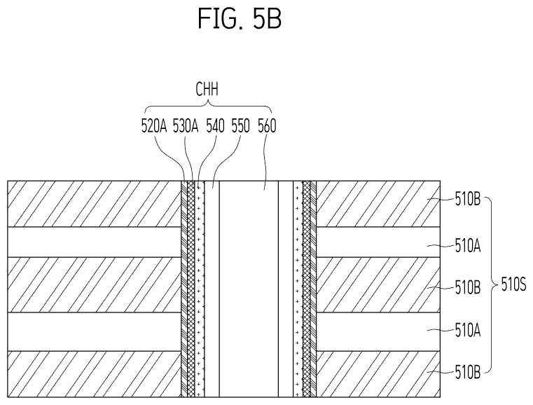

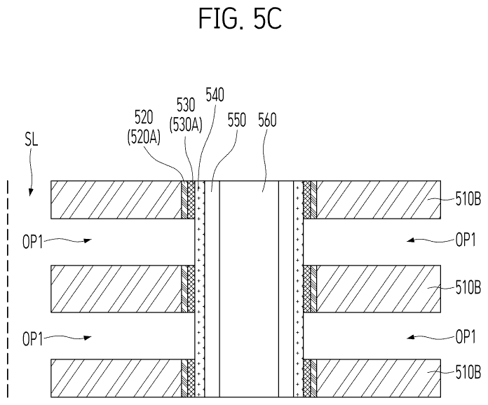

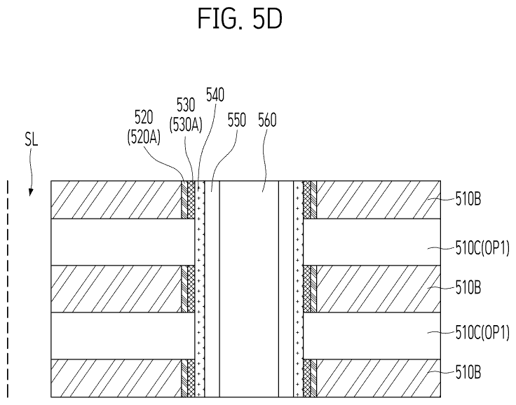

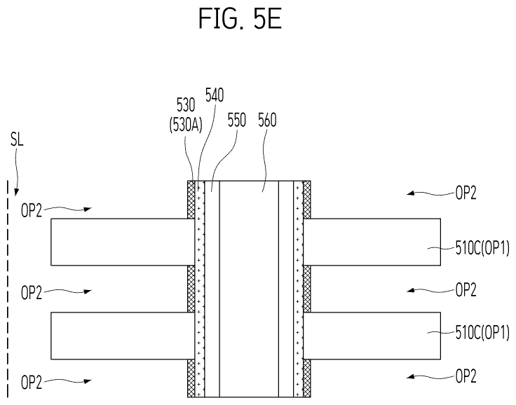

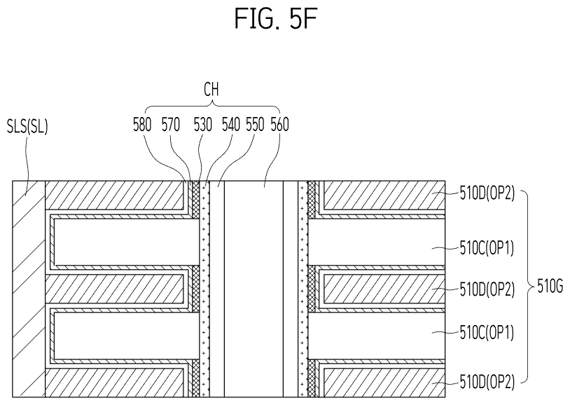

FIGS. 5A to 5F are diagrams for describing a manufacturing method of a semiconductor device in accordance with an embodiment. Hereinafter, the content overlapping with the previously described content will be omitted.

Referring to FIG. 5A, a stack 510S may be formed by alternately stacking first sacrificial layers 510A and second sacrificial layers 510B. Here, the second sacrificial layers 510B may be formed thicker than the first sacrificial layers 510A in the stacking direction. The first sacrificial layers 510A and the second sacrificial layers 510B may each include a sacrificial material such as oxide or nitride. For example, the first sacrificial layers 510A may each include oxide, and the second sacrificial layers 510B may each include nitride.

Referring to FIG. 5B, a channel hole CHH may be formed in the stack 510S. Subsequently, a buffer layer 520A may be formed in the channel hole CHH. Here, the buffer layer 520A may include a sacrificial material such as nitride.

Subsequently, a tunneling layer 530A may be formed in the channel hole CHH. For example, the tunneling layer 530A may be formed on the buffer layer 520A by a deposition method. Here, the tunneling layer 530A may include an insulating material such as oxide. For example, the tunneling layer 530A may include SiO₂.

Subsequently, a channel layer 540 may be formed in the tunneling layer 530A. The channel layer 540 may include a semiconductor material. For example, the channel layer 540 may include a semiconductor material such as polysilicon or germanium.

Subsequently, a first insulating core 550 may be formed in the channel layer 540. In an embodiment, the first insulating core 550 may be used to increase the mobility of charges in the channel layer 540. The first insulating core 550 may include nitride. For example, the first insulating core 550 may include silicon nitride.

Subsequently, a second insulating core 560 may be formed in the first insulating core 550. In an embodiment, the second insulating core 560 may improve the ability to prevent or mitigate the warpage of a wafer. The second insulating core 560 may include a material having stress different from that of the first insulating core 550. The second insulating core 560 may include oxide. For example, the second insulating core 560 may include at least one of Al₂O₃, HfO₂, and ZrO₂.

When the first insulating core 550 includes nitride, the first insulating core 150 may act as compressive stress on the wafer. When the second insulating core 560 includes oxide, the second insulating core 160 may act as tensile stress on the wafer. Accordingly, in an embodiment, the compressive stress of the first insulating core 550 and the tensile stress of the second insulating core 560 may be offset, and the ability to prevent or mitigate the warpage of the wafer may be improved.

Referring to FIG. 5C, a slit SL extending through the stack 510S may be formed.

Subsequently, first openings OP1 exposing the tunneling layer 530A may be formed by removing the first sacrificial layers 510A through the slit SL. First, the first openings OP1 exposing the buffer layer 520A may be formed by removing the first sacrificial layers 510A through the slit SL. Subsequently, the tunneling layer 530A may be exposed by partially removing the buffer layer 520A through the first openings OP1. Here, the buffer layer 520 remaining in regions corresponding to the second sacrificial layers 510B may be defined as buffer patterns 520.

In a process of partially removing the buffer layer 520A, portions of the second sacrificial layers 510B may be etched. This is because the buffer layer 520A and the second sacrificial layers 510B each include nitride, which is substantially the same sacrificial material. In such a case, the first openings OP1 may be expanded. Here, the first openings OP1 may have regions expanded so as to have a similar thickness to the second sacrificial layers 510B.

Subsequently, tunneling patterns 530 may be formed by etching the tunneling layer 530A through the first openings OP1. Here, the tunneling patterns 530 may be formed in regions corresponding to the second sacrificial layers 510B. In addition, the channel layer 540 may be exposed by etching the tunneling layer 530A through the first openings OP1.

Subsequently, at least one of hydrogen and deuterium may be injected into the channel layer 540 through the first openings OP1. In an embodiment, grain boundaries may exist in the channel layer 540, and when there are many grain boundaries, the mobility of charges in the channel layer 540 may be decreased. In an embodiment, when at least one of hydrogen and deuterium is injected into the channel layer 540, hydrogen or deuterium may be trapped at trap sites of the grain boundaries existing in the channel layer 540. In such a case, in an embodiment, the layer quality of the channel layer 540 may be improved, and the mobility of the charges may be increased.

Referring to FIG. 5D, insulating layers 510C may be formed in the first openings OP1 (i.e., 510C(OP1)). Here, the insulating layers 510C may be formed to have substantially the same thickness as the second sacrificial layers 510B in the stacking direction. In addition, the insulating layers 510C may include substantially the same material as the first sacrificial layers 510A. For example, the insulating layers 510C may each include an insulating material such as oxide.

Referring to FIG. 5E, second openings OP2 exposing the tunneling patterns 530 may be formed by removing the second sacrificial layers 510B through the slit SL. First, the second openings OP2 exposing the buffer patterns 520 may be formed by removing the second sacrificial layers 510B through the slit SL. Subsequently, the tunneling patterns 530 may be exposed by removing the buffer patterns 520 through the second openings OP2.

Subsequently, nitrogen may be injected into the tunneling patterns 530 through the second openings OP2. Through this, the tunneling patterns 530 may each include nitrogen oxide. For example, the tunneling patterns 530 may each include SiOₓN_{y} (0<x<1 and 0<y<1).

The tunneling patterns 530 may be used as passages through which the charges in the channel layer 540 are tunneled to a data storage layer when a bias is applied to a gate line. Here, an energy band gap of the tunneling patterns 530 may be adjusted by adjusting a composition of a material included in the tunneling patterns 530. For example, by injecting nitrogen into SiO₂ of the tunneling patterns 530, the tunneling patterns 530 may be made to each include SiOₓN_{y}, and the energy band gap of the tunneling patterns 530 may be reduced compared to when the tunneling patterns 530 each include only oxide (SiO₂). In such a case, even though a relatively small bias is applied, the charges in the channel layer 540 may be tunneled to the data storage layer through the tunneling patterns 530. Accordingly, in an embodiment, an operation voltage of a memory cell may be reduced, and a larger number of memory cells may be stacked.

An amount of charges tunneled from the channel layer 540 to the data storage layer may be adjusted by adjusting the composition of the material included in the tunneling patterns 530. According to an embodiment of the present disclosure, nitrogen may be injected into the tunneling patterns 530 so that a concentration of nitrogen is higher than a concentration of oxygen in a middle region of each of the tunneling patterns 530. Here, in an embodiment, a concentration of nitrogen may be lower than a concentration of oxygen in a region adjacent to the channel layer 540 and a region relatively spaced apart from the channel layer 540. In such a case, in an embodiment, a data storage capability of the data storage layer may be improved.

In addition, at least one of hydrogen and deuterium may be injected into the channel layer 540 through the second openings OP2. In such a case, hydrogen or deuterium may be trapped at the trap sites of the grain boundaries existing in the channel layer 540. Accordingly, in an embodiment, the layer quality of the channel layer 540 may be improved, and the mobility of the charges may be increased.

Referring to FIG. 5F, a data storage layer 570 may be formed. For example, the data storage layer 570 may be formed along inner surfaces of the slit SL and the second openings OP2. In an embodiment, the charges may be trapped in the data storage layer 570, and data may be stored in the form of bits. The data storage layer 570 may include silicon nitride. For example, the data storage layer 570 may include Si₃N₄.

Subsequently, a blocking layer 580 may be formed on the data storage layer 570. For example, the blocking layer 580 may be formed along a profile of the data storage layer 570. Consequently, a channel structure CH including the tunneling patterns 530, the channel layer 540, the first insulating core 550, the second insulating core 560, the data storage layer 570, and the blocking layer 580 may be formed.

In an embodiment, the blocking layer 580 may prevent or mitigate the charges from moving between the data storage layer 570 and the gate line. The blocking layer 580 may include silicon oxide. For example, the blocking layer 580 may include SiO₂. Alternatively, the blocking layer 580 may include a material having a high dielectric constant. For example, the blocking layer 580 may include at least one of Al₂O₃, HfO₂, and ZrO₂.

Subsequently, conductive layers 510D may be formed in the second openings OP2 (i.e., 510D(OP2)). Through this, a gate structure 510G in which the insulating layers 510C and the conductive layers 510D are alternately stacked may be formed. Here, the conductive layers 510D may be used as the gate lines. The conductive layers 510D may each include a conductive material. For example, the conductive layers 510D may each include a conductive material such as tungsten, molybdenum, or polysilicon.

Source select transistors, memory cells, or drain select transistors may be located in regions where the channel structure CH and the conductive layers 510D intersect each other. For example, at least one source select transistor, a plurality of memory cells, and at least one drain select transistor that are stacked along the channel structure CH may constitute one memory string.

According to the related art, a data storage layer may be formed in a shape in which it surrounds sidewalls of a channel layer, and data storage layers of stacked memory cells may be connected to each other. In an embodiment, an interval between conductive layers of a gate structure may be reduced in order to improve the degree of integration of a semiconductor device, and charges may move between the stacked memory cells. Accordingly, in an embodiment, reliability of the memory cell may decrease.

According to an embodiment of the present disclosure, the data storage layer 570 may be formed along the inner surfaces of the slit SL and the second openings OP2. In such a case, in an embodiment, the data storage layers constituting the memory cells may be spaced apart from each other, and it is possible to prevent or reduce a phenomenon in which the charges trapped in the data storage layers spread to adjacent regions. Accordingly, in an embodiment, the reliability of the memory cell may increase.

Subsequently, a slit structure SLS may be formed in the slit SL. The slit structure SLS may include an insulating material, a conductive material, or a semiconductor material.

According to an embodiment of the manufacturing method described above, the first openings OP1 may be formed by removing the first sacrificial layers 510A through the slit SL, and at least one of hydrogen and deuterium may be injected into the channel layer 540 through the first openings OP1. In addition, the second openings OP2 may be formed by removing the second sacrificial layers 510B through the slit SL, and at least one of hydrogen and deuterium may be injected into the channel layer 540 through the second openings OP2. In such a case, hydrogen or deuterium may be trapped at the trap sites of the grain boundaries existing in the channel layer 540. Accordingly, in an embodiment, the layer quality of the channel layer 540 may be improved, and the mobility of the charges may be increased.

In addition, nitrogen may be injected into the tunneling patterns 530 through the second openings OP2. In such a case, the tunneling patterns 530 may each include nitrogen oxide, and the concentration of nitrogen may be higher than the concentration of oxygen in the middle region of each of the tunneling patterns 530. Accordingly, in an embodiment, it is possible to reduce the operation voltage of the memory cell by making the energy band gap of the tunneling patterns 530 small, and it is possible to improve the data storage capability of the data storage layer 570 by increasing the amount of charges tunneled to the data storage layer 570.

In addition, the data storage layer 570 may be formed along the inner surfaces of the slit SL and the second openings OP2. In such a case, the data storage layers constituting the memory cells may be spaced apart from each other. Accordingly, in an embodiment, the reliability of the memory cell may increase.

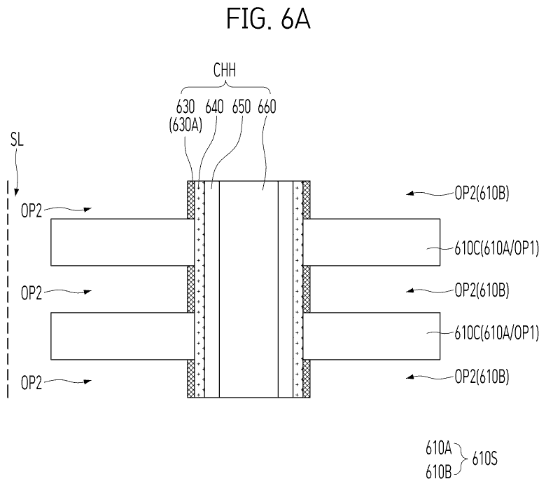

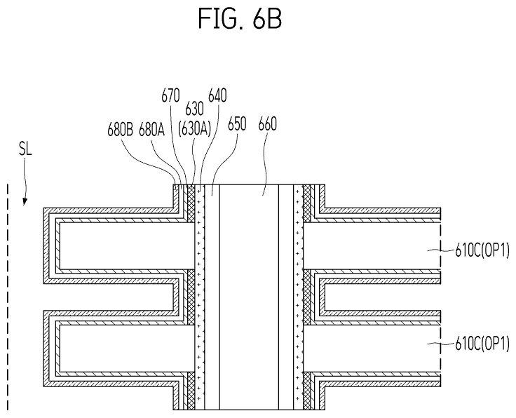

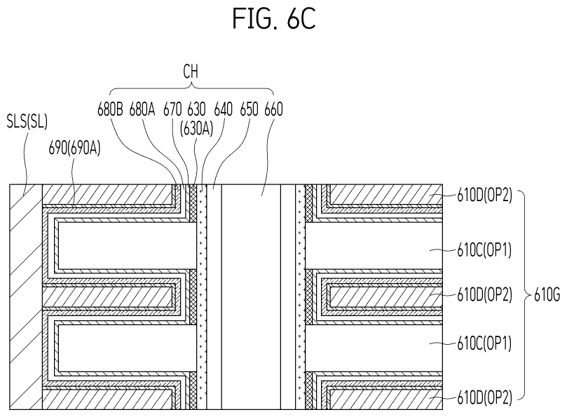

FIGS. 6A to 6C are diagrams for describing a manufacturing method of a semiconductor device in accordance with an embodiment. Hereinafter, the content overlapping with the previously described content will be omitted.

Referring to FIG. 6A, a stack 610S may be formed by alternately stacking first sacrificial layers 610A and second sacrificial layers 610B. The first sacrificial layers 610A may each include a sacrificial material such as oxide, and the second sacrificial layers 610B may each include a sacrificial material such as nitride.

Subsequently, a channel hole CHH extending through the stack 610S may be formed. Subsequently, a buffer layer, a tunneling layer 630A, a channel layer 640, a first insulating core 650, and a second insulating core 660 may be sequentially formed in the channel hole CHH. Here, the buffer layer may include a sacrificial material such as nitride, the tunneling layer 630A may include an insulating material such as oxide (SiO₂), the channel layer 640 may include a semiconductor material such as polysilicon, the first insulating core 650 may include an insulating material such as silicon nitride, and the second insulating core 660 may include an insulating material such as oxide.

Subsequently, a slit SL extending through the stack 610S may be formed.

Subsequently, first openings OP1 exposing the tunneling layer 630A may be formed by removing the first sacrificial layers 610A through the slit SL. First, the first openings OP1 exposing the buffer layer may be formed by removing the first sacrificial layers 610A through the slit SL. Subsequently, the tunneling layer 630A may be exposed by partially removing the buffer layer through the first openings OP1.

Subsequently, tunneling patterns 630 may be formed by etching the tunneling layer 630A through the first openings OP1. In addition, the channel layer 640 may be exposed by etching the tunneling layer 630A through the first openings OP1.

Subsequently, at least one of hydrogen and deuterium may be injected into the channel layer 640 through the first openings OP1. In such a case, hydrogen or deuterium may be trapped at trap sites of grain boundaries existing in the channel layer 640. Accordingly, in an embodiment, the layer quality of the channel layer 640 may be improved, and the mobility of charges may be increased.

Subsequently, insulating layers 610C may be formed in the first openings OP1. Here, the insulating layers 610C may include substantially the same material as the first sacrificial layers 610A. For example, the insulating layers 610C may each include an insulating material such as oxide.

Subsequently, second openings OP2 exposing the tunneling patterns 630 may be formed by removing the second sacrificial layers 610B through the slit SL. First, the second openings OP2 exposing the buffer layer remaining in regions corresponding to the second sacrificial layers 610B may be formed by removing the second sacrificial layers 610B through the slit SL. Subsequently, the tunneling patterns 630 may be exposed by removing the buffer layer through the second openings OP2.

Subsequently, nitrogen may be injected into the tunneling patterns 630 through the second openings OP2. Through this, the tunneling patterns 630 may each include nitrogen oxide. For example, the tunneling patterns 630 may each include SiOₓN_{y} (0<x<1 and 0<y<1).

In an embodiment, by injecting nitrogen into SiO₂ of the tunneling patterns 630, the tunneling patterns 630 may be made to each include SiOₓN_{y}, and an energy band gap of the tunneling patterns 630 may be reduced compared to when the tunneling patterns 630 each include only oxide (SiO₂). In such a case, even though a relatively small bias is applied, charges in the channel layer 640 may be tunneled to a data storage layer through the tunneling patterns 630. Accordingly, in an embodiment, an operation voltage of a memory cell may be reduced, and a larger number of memory cells may be stacked.

In addition, according to an embodiment of the present disclosure, nitrogen may be injected into the tunneling patterns 630 so that a concentration of nitrogen is higher than a concentration of oxygen in a middle region of each of the tunneling patterns 630. In such a case, in an embodiment, an amount of the tunneled charges may increase, and a data storage capability of the data storage layer may be improved.

In addition, at least one of hydrogen and deuterium may be injected into the channel layer 640 through the second openings OP2. In such a case, hydrogen or deuterium may be trapped at trap sites of grain boundaries existing in the channel layer 640. Accordingly, in an embodiment, the layer quality of the channel layer 640 may be improved, and the mobility of charges may be increased.

Referring to FIG. 6B, a data storage layer 670 may be formed along inner surfaces of the slit SL and the second openings OP2. The data storage layer 670 may include silicon nitride. For example, the data storage layer 670 may include Si₃N₄.

Subsequently, a first blocking layer 680A may be formed on the data storage layer 670. For example, the first blocking layer 680A may be formed along a profile of the data storage layer 670. Here, the first blocking layer 680A may include an insulating material such as oxide. For example, the first blocking layer 680A may include an insulating material such as SiO₂.

Subsequently, a second blocking layer 680B may be formed on the first blocking layer 680A. For example, the second blocking layer 680B may be formed along a profile of the first blocking layer 680A. Consequently, a channel structure CH including the tunneling patterns 630, the channel layer 640, the first insulating core 650, the second insulating core 660, the data storage layer 670, the first blocking layer 680A, and the second blocking layer 680B may be formed. Here, the second blocking layer 680B may include a material having a higher dielectric constant than the first blocking layer 680A. For example, the second blocking layer 680B may include oxide and may include at least one of Al₂O₃, HfO₂, and ZrO₂.

During an erase operation of the memory cell, charges of a gate line may be back-tunneled to the data storage layer 670. In such a case, the charges trapped in the data storage layer 670 might not be detrapped due to the back-tunneled charges. In an embodiment, when an operation of the memory cell is repeated in such a state, endurance of the memory cell may be weakened.

According to an embodiment of the present disclosure, the first blocking layer 680A and the second blocking layer 680B may be formed between the gate line and the data storage layer 670, and the first blocking layer 680A and the second blocking layer 680B may prevent or reduce a phenomenon in which the charges of the gate line are back-tunneled to the data storage layer 670. For example, in an embodiment, by additionally forming the second blocking layer 680B in addition to the first blocking layer 680A to increase a thickness of the blocking layers 680A and 680B through which the back-tunneled charges should tunnel, it is possible to reduce a back-tunneling phenomenon. In addition, in an embodiment, when the second blocking layer 680B includes the material having the higher dielectric constant than the first blocking layer 680A, energy required for the charges of the gate line to be tunneled through the second blocking layer 680B may increase, and it is possible to prevent or mitigate the charges from being back-tunneled.

Referring to FIG. 6C, a barrier layer 690A may be formed in the second openings OP2. For example, the barrier layer 690A may be formed along a profile of the second blocking layer 680B. The barrier layer 690A may include metal nitride. For example, the barrier layer 690A may include metal nitride, and may each include at least one of TaN and WN.

Subsequently, conductive layers 610D may be formed in the second openings OP2. Through this, a gate structure 610G in which the insulating layers 610C and the conductive layers 610D are alternately stacked may be formed. The conductive layers 610D may each include a conductive material. For example, the conductive layers 610D may each include a conductive material such as tungsten, molybdenum, or polysilicon.

Subsequently, the conductive layers 610D and the barrier layer 690A may be etched and partially removed through the slit SL so that the insulating layers 610C are exposed. Through this, barrier patterns 690 and the conductive layers 610D may remain in the second openings OP2. Here, the barrier patterns 690 and the conductive layers 610D may be used as gate lines.

In an embodiment, the barrier patterns 690 may be used to increase bonding strength of the conductive layers 610D. In addition, in an embodiment, the barrier patterns 690 may prevent or reduce a phenomenon in which the charges of the gate line are back-tunneled to the data storage layer 670. In an embodiment, the barrier patterns 670 may increase a magnitude of a work function required for the charges of the gate line to be back-tunneled. For example, when the conductive layers 610D and the barrier patterns 690 including at least one of TaN and WN are bonded to each other, the magnitude of the work function required for the charges of the conductive layers 610D to be back-tunneled may be increased compared to when the conductive layers 610D and barrier patterns including TiN are bonded to each other. In such a case, in an embodiment, energy required for back-tunneling may increase, and it is possible to prevent or mitigate the charges from being back-tunneled.

Subsequently, a slit structure SLS may be formed in the slit SL. The slit structure SLS may include an insulating material, a conductive material, or a semiconductor material.

According to an embodiment of the manufacturing method described above, the first blocking layer 680A and the second blocking layer 680B may be formed between the data storage layer 670 and the gate line. In such a case, in an embodiment, by increasing the thickness of the blocking layer 680A and 680B through which the charges of the gate line should tunnel, it is possible to reduce the back-tunneling phenomenon. In addition, the second blocking layer 680B may include the material having a higher dielectric constant than the first blocking layer 680A. In such a case, in an embodiment, energy required for the charges of the gate line to be back-tunneled may increase, and it is possible to prevent or mitigate the charges from being back-tunneled.

In addition, the barrier layer 690A may be formed before the conductive layers 610D are formed. The barrier layer 690A may increase the magnitude of the work function required for the charges of the gate line to be back-tunneled. In such a case, in an embodiment, the energy required for the charges of the gate line to be back-tunneled may increase, and it is possible to prevent or mitigate the charges from being back-tunneled.

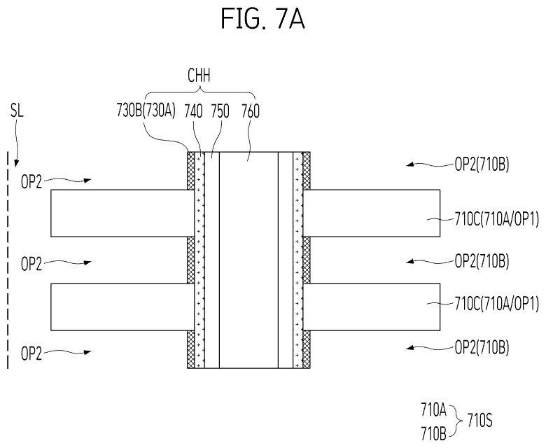

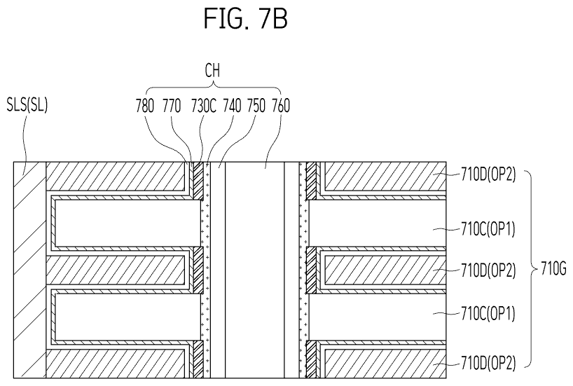

FIGS. 7A and 7B are diagrams for describing a manufacturing method of a semiconductor device in accordance with an embodiment. Hereinafter, the content overlapping with the previously described content will be omitted.

Referring to FIG. 7A, a stack 710S may be formed by alternately stacking first sacrificial layers 710A and second sacrificial layers 710B. The first sacrificial layers 710A may each include a sacrificial material such as oxide, and the second sacrificial layers 710B may each include a sacrificial material such as nitride.

Subsequently, a channel hole CHH extending through the stack 710S may be formed. Subsequently, a buffer layer, a tunneling layer 730A, a channel layer 740, a first insulating core 750, and a second insulating core 760 may be sequentially formed in the channel hole CHH.

Subsequently, a slit SL extending through the stack 710S may be formed.

Subsequently, first openings OP1 exposing the tunneling layer 730A may be formed by removing the first sacrificial layers 710A through the slit SL. First, the first openings OP1 exposing the buffer layer may be formed by removing the first sacrificial layers 710A through the slit SL. Subsequently, the tunneling layer 730A may be exposed by partially removing the buffer layer through the first openings OP1.

Subsequently, first tunneling patterns 730B may be formed by etching the tunneling layer 730A through the first openings OP1. In addition, the channel layer 740 may be exposed by etching the tunneling layer 730A through the first openings OP1.

Subsequently, at least one of hydrogen and deuterium may be injected into the channel layer 740 through the first openings OP1. In such a case, hydrogen or deuterium may be trapped at trap sites of grain boundaries existing in the channel layer 740. Accordingly, in an embodiment, the layer quality of the channel layer 740 may be improved, and the mobility of charges may be increased.

Subsequently, insulating layers 710C may be formed in the first openings OP1. Here, the insulating layers 710C may include substantially the same material as the first sacrificial layers 710A. For example, the insulating layers 710C may each include an insulating material such as oxide.

Subsequently, second openings OP2 exposing the first tunneling patterns 730B may be formed by removing the second sacrificial layers 710B through the slit SL. First, the second openings OP2 exposing the buffer layer remaining in regions corresponding to the second sacrificial layers 710B may be formed by removing the second sacrificial layers 710B through the slit SL. Subsequently, the first tunneling patterns 730B may be exposed by removing the buffer layer through the second openings OP2.

Referring to FIG. 7B, the channel layer 740 may be exposed by removing the first tunneling patterns 730B through the second openings OP2. Subsequently, second tunneling patterns 730C may be formed by oxidizing the channel layer 740. For example, the second tunneling patterns 730C may be formed by oxidizing polysilicon of the channel layer 740, and may each include SiO₂.

When tunneling patterns are formed by a deposition method, the tunneling patterns may each include SiO₂ having many impurities. For example, the tunneling patterns may each be formed of SiO₂ having a form in which not only Si and O are bonded to each other, but also Si and impurities such as a deposition gas are bonded to each other. In an embodiment, when a memory cell is repeatedly operated in such a state, an amount of charges tunneled through the tunneling patterns might not be constant, and the reliability of the memory cell may be decreased. According to an embodiment of the present disclosure, the second tunneling patterns 730C may be formed by oxidizing the channel layer 740. In such a case, the tunneling patterns may each include SiO₂ having relatively fewer impurities than when the tunneling patterns are formed by the deposition method. Accordingly, in an embodiment, by keeping an amount of charges tunneled through the tunneling patterns constant even though the memory cell is repeatedly operated, it is possible to improve the reliability of the memory cell.

Subsequently, nitrogen may be injected into the second tunneling patterns 730C through the second openings OP2. Through this, the second tunneling patterns 730C may each include nitrogen oxide. For example, the second tunneling patterns 730C may each include SiOₓN_{y} (0<x<1 and 0<y<1).

In an embodiment, by injecting nitrogen into SiO₂ of the second tunneling patterns 730C, the second tunneling patterns 730C may be made to each include SiOₓN_{y}, and an energy band gap of the second tunneling patterns 730C may be reduced compared to when the second tunneling patterns 730C each include only oxide (SiO₂). In such a case, in an embodiment, even though a relatively small bias is applied, charges in the channel layer 740 may be tunneled to a data storage layer through the second tunneling patterns 730C. Accordingly, in an embodiment, an operation voltage of the memory cell may be reduced, and a larger number of memory cells may be stacked.

In addition, according to an embodiment of the present disclosure, nitrogen may be injected into the second tunneling patterns 730C so that a concentration of nitrogen is higher than a concentration of oxygen in a middle region of each of the second tunneling patterns 730C. In such a case, in an embodiment, an amount of the tunneled charges may increase, and a data storage capability of the data storage layer may be improved.

In addition, at least one of hydrogen and deuterium may be injected into the channel layer 740 through the second openings OP2. In such a case, hydrogen or deuterium may be trapped at trap sites of grain boundaries existing in the channel layer 740. Accordingly, in an embodiment, the layer quality of the channel layer 740 may be improved, and the mobility of charges may be increased.

Subsequently, a data storage layer 770 may be formed along inner surfaces of the slit SL and the second openings OP2. Subsequently, a blocking layer 780 may be formed on the data storage layer 770. Consequently, a channel structure CH including the second tunneling patterns 730C, the channel layer 740, the first insulating core 750, the second insulating core 760, the data storage layer 770, and the blocking layer 780 may be formed. Subsequently, conductive layers 710D may be formed in the second openings OP2. Consequently, a gate structure 710G in which the insulating layers 710C and the conductive layers 710D are alternately stacked may be formed. Subsequently, a slit structure SLS may be formed in the slit SL (i.e., SLS(SL)).

According to an embodiment of the manufacturing method described above, the second tunneling patterns 730C may be formed by oxidizing the channel layer 740. In such a case, in an embodiment, the second tunneling patterns 730C including SiO₂ having relatively fewer impurities may be formed. Accordingly, in an embodiment, the reliability of the memory cell may be improved compared to when the tunneling patterns are formed by the deposition method.

In addition, in an embodiment, nitrogen may be injected into the second tunneling patterns 730C so that the concentration of nitrogen is higher than the concentration of oxygen in the middle region of each of the second tunneling patterns 730C. In such a case, in an embodiment, the data storage capability of the data storage layer 770 may be improved.

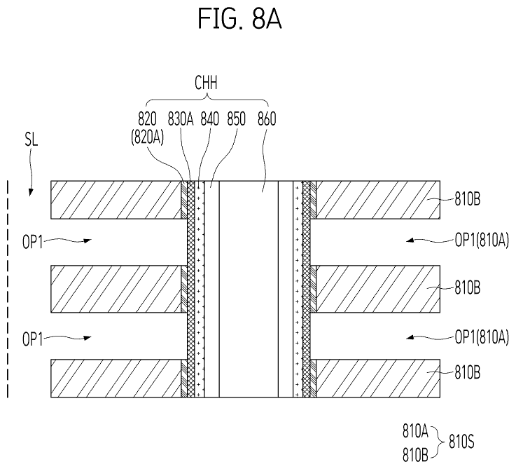

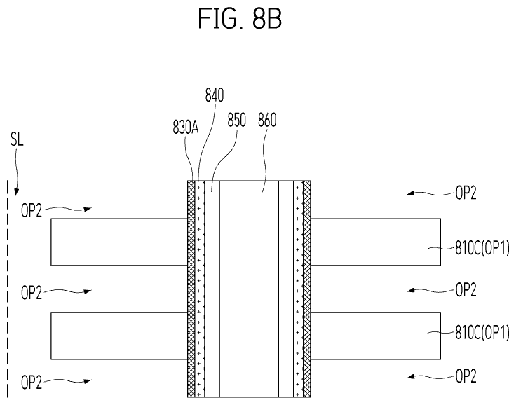

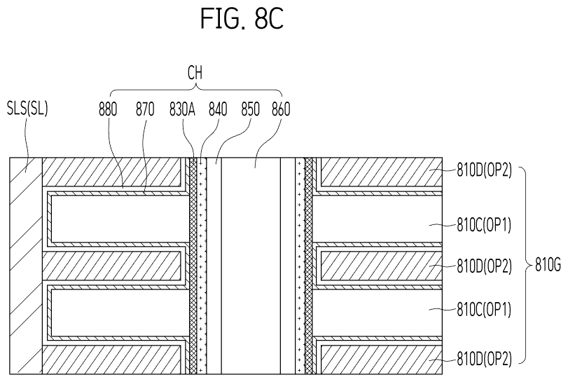

FIGS. 8A to 8C are diagrams for describing a manufacturing method of a semiconductor device in accordance with an embodiment. Hereinafter, the content overlapping with the previously described content will be omitted.

Referring to FIG. 8A, a stack 810S may be formed by alternately stacking first sacrificial layers 810A and second sacrificial layers 810B. The first sacrificial layers 810A may each include a sacrificial material such as oxide, and the second sacrificial layers 810B may each include a sacrificial material such as nitride.

Subsequently, a channel hole CHH extending through the stack 810S may be formed. Subsequently, a buffer layer 820A, a tunneling layer 830A, a channel layer 840, a first insulating core 850, and a second insulating core 860 may be sequentially formed in the channel hole CHH. Here, the buffer layer 820A may include a sacrificial material such as nitride, the tunneling layer 830A may include an insulating material such as oxide (SiO₂), the channel layer 840 may include a semiconductor material such as polysilicon, the first insulating core 850 may include an insulating material such as silicon nitride, and the second insulating core 860 may include an insulating material such as oxide.

Subsequently, a slit SL extending through the stack 810S may be formed.

Subsequently, first openings OP1 exposing the tunneling layer 830A may be formed by removing the first sacrificial layers 810A through the slit SL. First, the first openings OP1 exposing the buffer layer 820A may be formed by removing the first sacrificial layers 810A through the slit SL. Subsequently, the tunneling layer 830A may be exposed by partially removing the buffer layer 820A through the first openings OP1. Here, the buffer layer 820A remaining in regions corresponding to the second sacrificial layers 810B may be defined as buffer patterns 820.

Subsequently, nitrogen may be injected into the tunneling layer 830A through the first openings OP1. In other words, compared to FIGS. 5C, 6A, and 7A, portions of the tunneling layer 830A might not be removed through the first openings OP1, and nitrogen may be injected into the tunneling layer 830A through the first openings OP1. Through this, the tunneling layer 830A may include nitrogen oxide. For example, the tunneling layer 830A may include SiOₓN_{y} (0<x<1 and 0<y<1). Here, nitrogen may be injected into the tunneling layer 830A so that a concentration of nitrogen is higher than a concentration of oxygen in a region adjacent to the channel layer 840. In such a case, an amount of charges tunneled in the region adjacent to the channel layer 840 may decrease.

However, the present disclosure is not limited thereto, and a process of injecting nitrogen into the tunneling layer 830A through the first openings OP1 may be omitted. In such a case, the tunneling layer 830A may include oxide (SiO₂).

In addition, at least one of hydrogen and deuterium may be injected into the channel layer 840 through the first openings OP1. In such a case, hydrogen or deuterium may be trapped at trap sites of grain boundaries existing in the channel layer 840. Accordingly, in an embodiment, the layer quality of the channel layer 840 may be improved, and the mobility of charges may be increased.

Referring to FIG. 8B, insulating layers 810C may be formed in the first openings OP1 (i.e., 810C(OP1)). Here, the insulating layers 810C may include substantially the same material as the first sacrificial layers 810A. For example, the insulating layers 810C may each include an insulating material such as oxide.

Subsequently, second openings OP2 exposing the tunneling layer 830A may be formed by removing the second sacrificial layers 810B through the slit SL. First, the second openings OP2 exposing the buffer patterns 820 may be formed by removing the second sacrificial layers 810B through the slit SL. Subsequently, the tunneling layer 830A may be exposed by removing the buffer patterns 820 through the second openings OP2.

Subsequently, nitrogen may be injected into the tunneling layer 830A through the second openings OP2. Through this, the tunneling layer 830A may include nitrogen oxide. For example, the tunneling layer 830A may include SiOₓN_{y} (0<x<1 and 0<y<1). In addition, nitrogen may be injected into the tunneling layer 830A so that a concentration of nitrogen is higher than a concentration of oxygen in a middle region of the tunneling layer 830A. In such a case, in an embodiment, an amount of the tunneled charges may increase, and a data storage capability of the data storage layer may be improved.

In addition, at least one of hydrogen and deuterium may be injected into the channel layer 840 through the second openings OP2. In such a case, hydrogen or deuterium may be trapped at trap sites of grain boundaries existing in the channel layer 840. Accordingly, in an embodiment, the layer quality of the channel layer 840 may be improved, and the mobility of charges may be increased.

Referring to FIG. 8C, a data storage layer 870 may be formed along inner surfaces of the slit SL and the second openings OP2. Subsequently, a blocking layer 880 may be formed on the data storage layer 870. Consequently, a channel structure CH including the tunneling layer 830A, the channel layer 840, the first insulating core 850, the second insulating core 860, the data storage layer 870, and the blocking layer 880 may be formed. Subsequently, conductive layers 810D may be formed in the second openings OP2. Consequently, a gate structure 810G in which the insulating layers 810C and the conductive layers 810D are alternately stacked may be formed. Subsequently, a slit structure SLS may be formed in the slit SL (i.e., SLS(SL)).

In such a case, in regions corresponding to the conductive layers 810D, an amount of charges tunneled to the data storage layer 870 through the tunneling layer 830A may increase. In addition, in regions corresponding to the insulating layers 810C, an amount of charges tunneled to the data storage layer 870 through the tunneling layer 830A may decrease. Accordingly, in an embodiment, an amount of charges tunneled in regions of memory cells may be increased, and an amount of charges tunneled in regions other than the memory cells may be decreased, such that it is possible to improve the data storage capability of the data storage layer 870.

According to an embodiment of the manufacturing method described above, portions of the tunneling layer 830A might not be removed, and nitrogen may be injected into the tunneling layer 830A through the first openings OP1 and the second openings OP2. However, embodiments of the present disclosure are not limited thereto, and a process of injecting nitrogen into the tunneling layer 830A through the first openings OP1 may be omitted. In such a case, in an embodiment, the tunneling layer 830A may include SiO₂ in regions corresponding to the first openings OP1, and may include SiOₓN_{y} in regions corresponding to the second openings OP2.

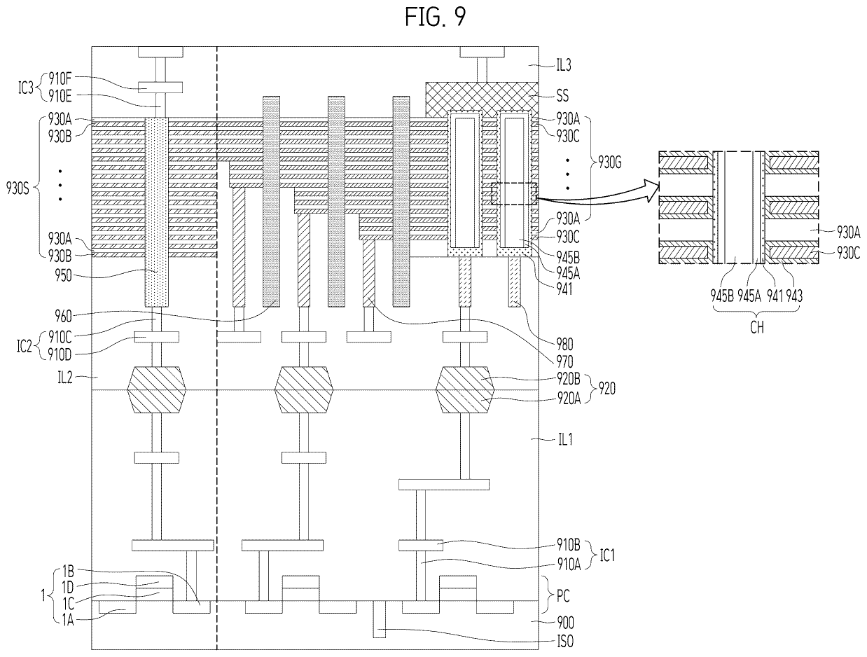

FIG. 9 is a diagram for describing a semiconductor device in accordance with an embodiment. Hereinafter, the content overlapping with the previously described content will be omitted.

Referring to FIG. 9, the semiconductor device may include a substrate 900, a peripheral circuit PC, a source structure SS, a bonding structure 920, a stack 930S, a gate structure 930G, channel structures CH, a through plug 950, supports 960, a first contact via 970, second contact vias 980, an element isolation layer ISO, a first interconnection structure IC1, a second interconnection structure IC2, a third interconnection structure IC3, a first interlayer insulating layer IL1, a second interlayer insulating layer IL2, and a third interlayer insulating layer IL3.

The peripheral circuit PC may be located on the substrate 900. The peripheral circuit PC may include a transistor 1. The transistor 1 may include junctions 1A and 1B, a gate electrode 1D, and a gate insulating layer 1C. The element isolation layer ISO may be located in the substrate 900, and an active region of the transistor 1 may be defined by the element isolation layer ISO.

The first interconnection structure IC1 may be located on the peripheral circuit PC. The first interconnection structure IC1 may be located in the first interlayer insulating layer IL1. Here, the first interlayer insulating layer IL1 may be located on the substrate 900. The first interconnection structure IC1 may include first vias 910A and first wiring lines 910B. The first interconnection structure IC1 may include a conductive material such as tungsten. The first interlayer insulating layer IL1 may include an insulating material such as oxide or nitride.

The bonding structure 920 may be located over the peripheral circuit PC. For example, the bonding structure 920 may be located on the first interconnection structure IC1. The bonding structure 920 may include first bonding pads 920A and second bonding pads 920B. The first bonding pads 920A may be located in the first interlayer insulating layer IL1. The second bonding pads 920B may be located on the first bonding pads 920A, and may be located in the second interlayer insulating layer IL2. Here, the second interlayer insulating layer IL2 may be located on the first interlayer insulating layer IL1. The bonding structure 920 may include a conductive material such as copper. The second interlayer insulating layer IL2 may include an insulating material such as oxide.

The second interconnection structure IC2 may be located over the bonding structure 920. The second interconnection structure IC2 may be located in the second interlayer insulating layer IL2. The second interconnection structure IC2 may include second vias 910C and second wiring lines 910D. The second interconnection structure IC2 may be connected to the bonding structure 920. For example, at least one of the second vias 910C may be connected to the second bonding pad 920B. The second interconnection structure IC2 may include a conductive material such as tungsten.

The stack 930S may be located over the bonding structure 920. For example, the stack 930S may be located on the second interconnection structure IC2. The stack 930S may include insulating layers 930A and sacrificial layers 930B that are alternately stacked. The gate structure 930G may be located at a level corresponding to the stack 930S. The gate structure 930G may include insulating layers 930A and conductive layers 930C that are alternately stacked. The gate structure 930G may include an inverted staircase structure in which lower surfaces of the conductive layers 930C are exposed.

For reference, the terms “upper” and “lower” as used herein may be relative concepts for convenience of explanation. For example, the gate structure 930G may include a staircase structure in which upper surfaces of the conductive layers 930C are exposed. A state in which the gate structure 930G is rotated has been illustrated in FIG. 9. In other words, the gate structure 930G including the inverted staircase structure has been illustrated in FIG. 9.

The through plug 950 may extend through the stack 930S and the second interlayer insulating layer IL2. The through plug 950 may be electrically connected to the peripheral circuit PC through the bonding structure 920. For example, the through plug 950 may be connected to the bonding structure 920 through the second interconnection structure IC2, and may be electrically connected to the peripheral circuit PC through the bonding structure 920. The through plug 950 may include a conductive material such as tungsten. However, the present disclosure is not limited thereto, and the through plug 950 is a support and may include an insulating material such as oxide.

The channel structures CH may extend into the source structure SS through the gate structure 930G. Here, the source structure SS may be located on the gate structure 930G. Each of the channel structures CH may include at least one of a channel layer 941, a memory layer 943, a first insulating core 945A, and a second insulating core 945B. Here, the channel layer 941 may be connected to the source structure SS.

For reference, the channel structures CH may correspond to the channel structures CH of FIGS. 1A to 1C. For example, the channel layer 941 may correspond to the channel layer 130 of FIGS. 1A to 1C, the memory layer 943 may correspond to the memory layer 140 of FIGS. 1A to 1C, and the first insulating core 945A and the second insulating core 945B may correspond to the first insulating core 150 and the second insulating core 160 of FIGS. 1A to 1C.

However, the present disclosure is not limited thereto, and the channel structures CH may correspond to the channel structures CH of FIGS. 2A and 2B. For example, the channel layer 941 may correspond to the channel layer 230 of FIGS. 2A and 2B, the memory layer 943 may correspond to the memory layer 240 of FIGS. 2A and 2B, and the first insulating core 945A and the second insulating core 945B may correspond to the first insulating core 250 and the second insulating core 260 of FIGS. 2A and 2B. In addition, the channel structures CH may correspond to the channel structures CH of FIGS. 3A and 3B. For example, the channel layer 941 may correspond to the channel layer 330 of FIGS. 3A and 3B, the memory layer 943 may correspond to the memory layer 340 of FIGS. 3A and 3B, and the first insulating core 945A and the second insulating core 945B may correspond to the first insulating core 350 and the second insulating core 360 of FIGS. 3A and 3B.

The supports 960 may extend into the third interlayer insulating layer IL3 through the gate structure 930G. Here, the third interlayer insulating layer IL3 may be located on the gate structure 930G and/or the stack 930S. The supports 960 may each include an insulating material such as oxide. The third interlayer insulating layer IL3 may include an insulating material such as oxide.

The first contact vias 970 may be respectively connected to the conductive layers 930C of the gate structure 930G. For example, the first contact vias 970 may extend through the second interlayer insulating layer IL2 and be respectively connected to the conductive layers 930C whose lower surfaces are exposed through the inverted staircase structure of the gate structure 930G. The first contact vias 970 may each include a conductive material such as tungsten.

The second contact vias 980 may be connected to the channel structures CH, respectively. For example, the second contact vias 980 may extend through the second interlayer insulating layer IL2 and be respectively connected to the channel layers 941 of the channel structures CH. The second contact vias 980 may each include a conductive material such as tungsten.

The third interconnection structure IC3 may be located in the third interlayer insulating layer IL3. The third interconnection structure IC3 may include third vias 910E and third wiring lines 910F. At least one of the third vias 910E may be connected to the first contact via 970. At least one of the third vias 910E may be connected to the source structure SS. At least one of the third wiring lines 910F may be connected to the third via 910E. The third interconnection structure IC3 may include a conductive material such as tungsten.

According to the structure described above, the semiconductor device may include the bonding structure 920. The bonding structure 920 may be located over the peripheral circuit PC, and may be electrically connected to the peripheral circuit PC.

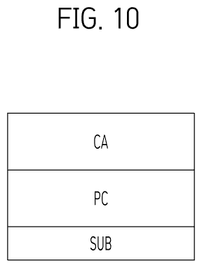

FIG. 10 is a configuration diagram of a semiconductor device in accordance with an embodiment. Hereinafter, the content overlapping with the previously described content will be omitted.

Referring to FIG. 10, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. As an example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operation voltage, and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

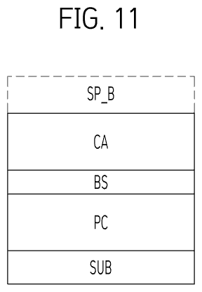

FIG. 11 is a configuration diagram of a semiconductor device in accordance with an embodiment. Hereinafter, the content overlapping with the previously described content will be omitted.

Referring to FIG. 11, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be used as the bonding structure BS. As an example, an interconnection structure included in the memory cell array CA and an interconnection structure included in the peripheral circuit PC may be directly bonded to each other. In such a case, a bit line, a source line, and the like, may be used as the bonding structure without a separate bonding pad.

Other configurations may be the same as or similar to those described above with reference to FIG. 10.

Meanwhile, it is also possible for the semiconductor device to have a structure in which embodiments described above with reference to FIGS. 10 and 11 are combined with each other or have a partially modified structure. In embodiments described with reference to FIGS. 10 and 11, locations of the memory cell array CA and the peripheral circuit PC may be changed. At least one memory cell array CA and/or at least one peripheral circuit PC may be additionally bonded to each other in an embodiment described with reference to FIG. 11. As an example, a portion of the peripheral circuit PC may be located in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including insulating layers and conductive layers, the insulating layers and the conductive layers alternately stacked with each other;
a slit structure extending through the gate structure in the stacked direction;
a channel layer extending through the gate structure in the stacked direction;
a data storage layer including a first portion located between each of the conductive layers and the channel layer, a second portion located between each of the insulating layers and the slit structure, and a third portion extending in a horizontal direction to connect the first portion and the second portion to each other; and
tunneling patterns located between the conductive layers and the channel layer, respectively, and separated from each other by the insulating layers.

2. The semiconductor device of claim 1, further comprising a first blocking layer located between the slit structure and the data storage layer and extending along a profile of the data storage layer.

3. The semiconductor device of claim 2, further comprising a second blocking layer located between the slit structure and the first blocking layer and extending along a profile of the first blocking layer.

4. The semiconductor device of claim 3, wherein the second blocking layer includes a material having a higher dielectric constant than the first blocking layer.

5. The semiconductor device of claim 4, wherein the first blocking layer includes silicon oxide, and the second blocking layer includes at least one of aluminum oxide, hafnium oxide, and zirconium oxide.

6. The semiconductor device of claim 5, wherein the first blocking layer includes SiO₂, and the second blocking layer includes at least one of Al₂O₃, HfO₂, and ZrO₂.

7. The semiconductor device of claim 1, further comprising:
a first insulating core located in the channel layer; and
a second insulating core located in the first insulating core and having a stress different from that of the first insulating core.

8. The semiconductor device of claim 7, the first insulating core includes nitride, and
the second insulating core includes oxide.

9. The semiconductor device of claim 1, wherein the channel layer includes at least one of hydrogen and deuterium.

10. The semiconductor device of claim 1, wherein the tunneling patterns each include nitrogen oxide.

11. The semiconductor device of claim 10, wherein the tunneling patterns each include SiOₓN_{y},
wherein x is greater than zero and less than 1,
wherein y is greater than zero and less than 1,
wherein each of the tunneling patterns include a concentration of nitrogen higher than a concentration of oxygen in a middle region of each of the tunneling patterns, and
wherein each of the tunneling patterns include a concentration of nitrogen lower than a concentration of oxygen in a region of each of the tunneling patterns adjacent to the channel layer and a region of each of the tunneling patterns adjacent to the data storage layer.

12. The semiconductor device of claim 1, further comprising barrier patterns surrounding the conductive layers.

13. The semiconductor device of claim 1, wherein the tunneling patterns protrude into the channel layer.

14. The semiconductor device of claim 13, wherein the channel layer has a first thickness in the stacking direction at a level corresponding to the insulating layers and has a second thickness in the stacking direction smaller than the first thickness at a level corresponding to the conductive layers.

15. A semiconductor device comprising:
a peripheral circuit;
a bonding structure located over the peripheral circuit;
a gate structure located over the bonding structure and including insulating layers and conductive layers that are alternately stacked;
a slit structure extending through the gate structure in the stacked direction;
a source structure located on the gate structure; and
a channel structure extending into the source structure through the gate structure in the stacked direction and including a channel layer, a data storage layer, and tunneling patterns,
wherein the data storage layer includes a first portion located between each of the conductive layers and the channel layer, a second portion located between each of the insulating layers and the slit structure, and a third portion extending in a horizontal direction to connect the first portion and the second portion to each other.

16. The semiconductor device of claim 15, wherein the tunneling patterns are located between the conductive layers and the channel layer, respectively, and are separated from each other by the insulating layers.

17. The semiconductor device of claim 15, wherein the tunneling patterns each include SiOₓN_{y},
Wherein x is greater than zero and less than 1,
wherein y is greater than zero and less than 1,
wherein each of the tunneling patterns include a concentration of nitrogen higher than a concentration of oxygen in a middle region of each of the tunneling patterns, and
wherein each of the tunneling patterns include a concentration of nitrogen lower than a concentration of oxygen in a region of each of the tunneling patterns adjacent to the channel layer and a region of each of the tunneling patterns adjacent to the data storage layer.

18. The semiconductor device of claim 15, further comprising:
a first blocking layer located between the slit structure and the data storage layer and extending along a profile of the data storage layer;
a second blocking layer located between the slit structure and the first blocking layer and extending along a profile of the first blocking layer;
a first insulating core located in the channel layer; and
a second insulating core located in the first insulating core and having stress different from that of the first insulating core.

19. The semiconductor device of claim 15, further comprising:
a through plug located overt the bonding structure and electrically connected to the peripheral circuit;
a first interconnection structure connecting the peripheral circuit and the bonding structure to each other; and
a second interconnection structure connecting the bonding structure and the through plug to each other.
